(19) United States
(12) Patent Application Publication
(10) Pub. No.: US 2026/0090173 A1
(43) Pub. Date: Mar. 26, 2026

(54) Cover Window Integration for Light Emitting Diode Panels

(71) Applicant: Apple Inc., Cupertino, CA (US)

(72) Inventors: Rong Liu, Cupertino, CA (US); Shuhong Liu, San Jose, CA (US); Martin R. Kardasz, Mountain View, CA (US); Jun Qi, San Jose, CA (US); Lina He, San Jose, CA (US); Ian D. St. Louis, San Diego, CA (US); Clayton K. Chan, Fremont, CA (US); Justin S. Brockman, Menlo Park, CA (US); Yong Seok Choi, Pleasanton, CA (US); Xia Li, San Jose, CA (US); Mark James Holmes, San Jose, CA (US); Fang Ou, San Diego, CA (US); Jason H. Choi, Sunnyvale, CA (US); Victor H. Yin, Cupertino, CA (US)

(21) Appl. No.: 19/327,677

(22) Filed: Sep. 12, 2025

Related U.S. Application Data
(60) Provisional application No. 63/698,942, filed on Sep. 25, 2024.

(51) Int. Cl. H10H 29/853; H10H 29/01; H10H 29/856

(52) U.S. Cl. CPC H10H 29/853; H10H 29/012; H10H 29/0362; H10H 29/856

(57) ABSTRACT

Optoelectronic structures and methods of assembly are described. In an embodiment, an optoelectronic structure includes a frontplane directly bonded to a backplane, and a cover window attached to the frontplane so that a cavity forms between the cover window and an optical layer of the frontplane. In an embodiment, the width of the cover window is less than the width of the backplane. In an embodiment, the width of the cover window is equal to the width of the backplane.

### RELATED APPLICATIONS

This application claims the benefit of priority of U.S. Provisional Application No. 63/698,942, filed Sep. 25, 2024, which is herein incorporated by reference.

### BACKGROUND

### Field

Embodiments described herein relate to optoelectronic structures. More specifically, embodiments relate to optoelectronic structures with micro-sized light emitting or sensing diodes.

### Background Information

State of the art displays for portable electronics, computers, and televisions commonly utilize glass substrates with thin film transistors (TFTs) to control transmission of backlight through pixels based on liquid crystals. More recently emissive displays such as those based on organic light emitting diodes (OLEDs) have been introduced. Even more recently, it has been proposed to integrate emissive inorganic semiconductor-based micro-LEDs into displays. Micro-LED integration however can require mass transfer techniques of micro-LEDs from growth substrates based on non-silicon materials, such as sapphire, gallium nitride, etc.

### SUMMARY

Embodiments describe optoelectronic structures and methods of assembly. In an embodiment, an optoelectronic structure includes a frontplane directly bonded to a backplane, where the frontplane includes an array of micro-sized diodes. Further, the optoelectronic structure includes a cover window located over the array of micro-sized diodes and a cavity located between the cover window and the array of micro-sized diodes, where the cavity is an air gap. In an embodiment, the width of the cover window is less than the width of the backplane. In an embodiment, the width of the cover window is the same as the width of the backplane.

### BRIEF DESCRIPTION OF THE DRAWINGS

FIG. 1A is a cross-sectional side view illustration of an optoelectronic structure including a cover window of a first width in accordance with an embodiment.

FIG. 1B is a cross-sectional side view illustration of an optoelectronic structure including a cover window of a second width in accordance with an embodiment.

FIG. 1C is a cross-sectional side view illustration of multiple optoelectronic structures each including a cover window in accordance with an embodiment.

FIG. 1D is a cross-sectional side view illustration of multiple optoelectronic structures including a cover window that spans over the multiple optoelectronic structures in accordance with an embodiment.

FIG. 1E is a cross-sectional side view illustration of an optoelectronic structure including a cover window with chamfered edges in accordance with an embodiment.

FIG. 2A is a cross-sectional side view illustration of a cover window embedded within a frame structure in accordance with an embodiment.

FIG. 2B is a cross-sectional side view illustration of a recessed cover window in accordance with an embodiment.

FIG. 2C is a cross-sectional side view illustration of a recessed optical layer in accordance with an embodiment.

FIG. 3 is a flow chart for a first method for assembling an optoelectronic structure in accordance with an embodiment.

FIGS. 4A-4F are schematic cross-sectional side view illustrations of a first method for assembling an optoelectronic structure in accordance with an embodiment.

FIG. 5 is a flow chart for a second method for assembling an optoelectronic structure in accordance with an embodiment.

FIGS. 6A-6D are schematic cross-sectional side view illustrations of a second method for assembling an optoelectronic structure in accordance with an embodiment.

FIG. 7 is a flow chart for a third method for assembling an optoelectronic structure in accordance with an embodiment.

FIGS. 8A-8G are schematic cross-sectional side view illustrations of a third method for assembling an optoelectronic structure in accordance with an embodiment.

FIG. 9 is a flow chart for a fourth method for assembling an optoelectronic structure in accordance with an embodiment.

FIGS. 10A-10F are schematic cross-sectional side view illustrations of a fourth method for assembling an optoelectronic structure in accordance with an embodiment.

FIG. 11 is a flow chart for a fifth method for assembling an optoelectronic structure in accordance with an embodiment.

FIG. 12A-12H are schematic cross-sectional side view illustrations of a fifth method for assembling an optoelectronic structure in accordance with an embodiment.

FIG. 13 is a flow chart for a sixth method for assembling an optoelectronic structure in accordance with an embodiment.

FIG. 14A-14G are schematic cross-sectional side view illustrations of a sixth method for assembling an optoelectronic structure in accordance with an embodiment.

FIG. 15 is a flow chart for a seventh method for assembling an optoelectronic structure in accordance with an embodiment.

FIGS. 16A-16H are schematic cross-sectional side view illustrations of a seventh method for assembling an optoelectronic structure in accordance with an embodiment.

FIG. 17 is a flow chart for an eighth method for assembling an optoelectronic structure in accordance with an embodiment.

FIGS. 18A-18H are schematic cross-sectional side view illustrations of an eighth method for assembling an optoelectronic structure in accordance with an embodiment.

### DETAILED DESCRIPTION

Micro-LEDs show promise for various applications due to their high brightness, efficiency, and potential for miniaturization. It has been observed that the incorporation of air gaps within micro-LED structures can enhance optical performance. In particular, the incorporation of an air gap between a micro-sized diode (or array of micro-sized diodes) and a cover window may improve light extraction efficiency, reduce artifacts caused by reflections, and minimize absorption losses. However, the integration of the cover window at the die level may be problematic in that such integration may not be highly reproducible at the die level and may even compromise the integrity of the air gap. In embodiments, optoelectronic structures and methods of assembly are described in which a cover window may be integrated at the wafer level. In an embodiment, an optoelectronic structure may include a cover window located over an array of micro-sized diodes, and a cavity (e.g., air gap) located between the cover window and the array of micro-sized diodes. In this way, by integrating the cover window at the wafer level, the optoelectronic structures and methods described may include an air gap that is highly reproducible and enhances the optical performance of micro-LEDs.

In addition, it has been observed that the integration of cover windows at the wafer level may affect other aspects or components of a micro-LED structure during fabrication. For example, during backgrinding a silicon substrate to expose through-silicon vias (and to ultimately form backside routing layers) on a backplane of a micro-LED structure, the cover windows bonded to a frontplane of the micro-LED structure may generate localized stresses along the frontplane. In such instances, the localized stresses along the frontplane coupled with the loss of stiffness of the now thinner backplane may cause warpage of the backplane during backgrinding. In embodiments, the width of the cover window may be controlled so as to reduce, and in some instances eliminate, these localized stresses in the frontplane caused by the cover windows during the backgrinding operation. In an embodiment, an optoelectronic structure may include a cover window located over an array of micro-sized diodes, and a cavity (e.g., air gap) located between the cover window and the array of micro-sized diodes, where the width of the cover window may be approximately the same as the width as the backplane. In such instances, the integration of the cover window may occur before the backgrinding operation, where the width of the cover window reduces the localized stresses in the frontplane during backgrinding. In an embodiment, an optoelectronic structure may include a cover window located over an array of micro-sized diodes, and a cavity (e.g., air gap) located between the cover window and the array of micro-sized diodes, where the width of the cover window may be less than the width of the backplane. In such instances, the integration of the cover window may occur after the backgrinding operation, which effectively eliminates the localized stresses in the frontplane during backgrinding since the cover windows have not yet been attached.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

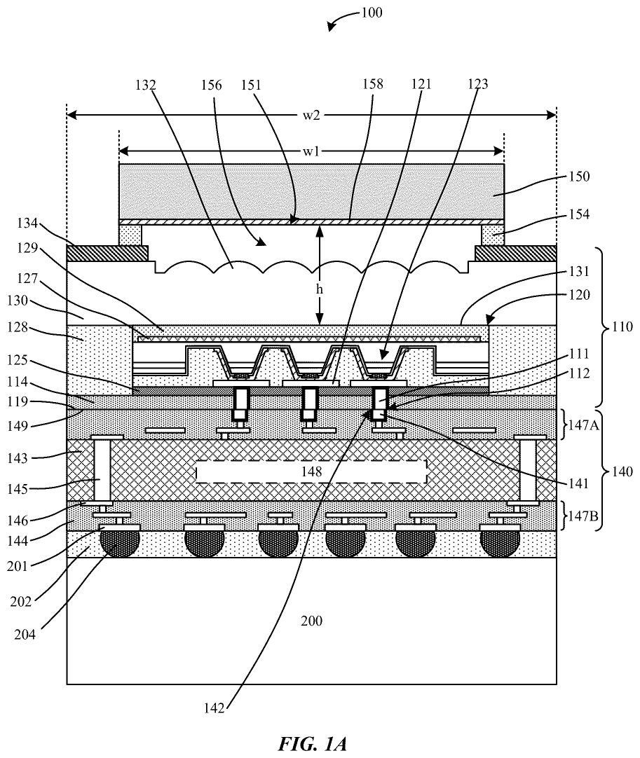

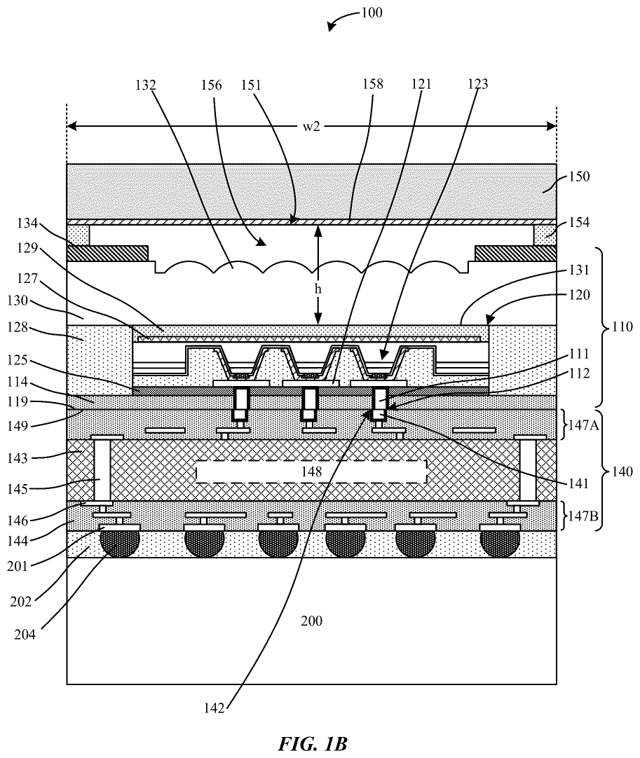

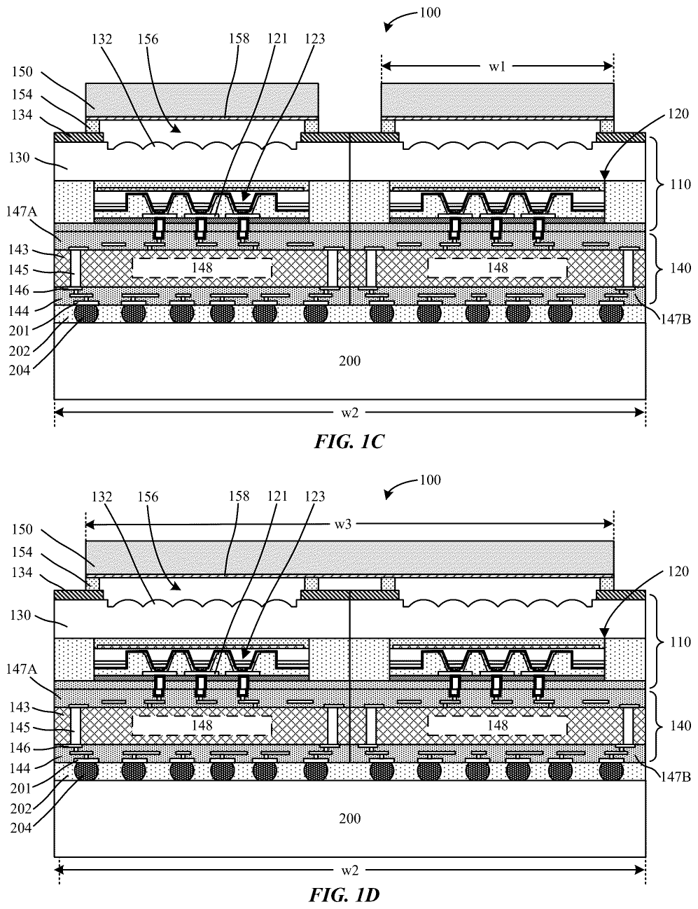

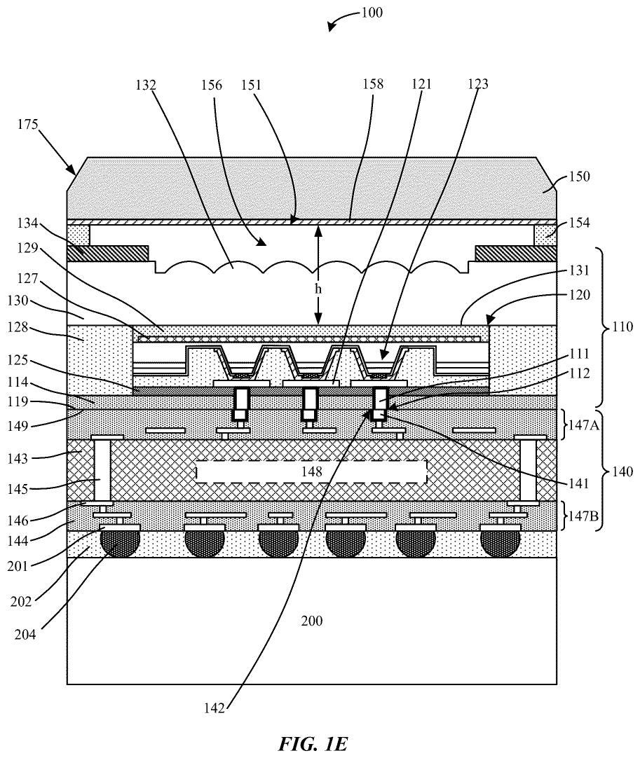

Referring now to FIG. 1A, a cross-sectional side view illustration is provided of an optoelectronic structure 100 in accordance with an embodiment. In the example of FIG. 1A, optoelectronic structure 100 may include a frontplane 110 directly bonded to backplane 140. Further, optoelectronic structure 100 illustrated in FIG. 1A may represent only a portion of a larger frontplane (e.g., reconstituted substrate, etc.) bonded to a larger backplane (e.g., complementary metal-oxide-semiconductor (“CMOS”) backplane wafer, etc.) from which a plurality of optoelectronic structures may be singulated. In the example of FIG. 1A, frontplane 110 may include coupon 120 and optical layer 130. Coupon 120 may include an array of landing pads 121 underneath an array of micro-sized diodes 123 (e.g., micro-LEDs, photodetectors, etc.), where each landing pad corresponds to a micro-sized diode. Further, the micro-sized diodes may be designed for the emission of primary red light (e.g. 600-700 nm wavelength), primary green light (e.g. 495-570 nm wavelength), or primary blue light (e.g. 450-495 nm wavelength), though embodiments are not limited to these exemplary emission spectra. In addition, as used herein, the term “micro-sized diodes” or “micro-LEDs” may refer to the maximum lateral dimension of the device. In some embodiments, the “micro” sized diodes may have a maximum lateral dimension below 100 μm, such as below 10 μm, 5 μm, 0.5 μm, or less, and may form both monochromatic and full color optoelectronic structures, such as displays and sensors.

In further reference to FIG. 1A, frontplane 110 may also include a top contact layer 127 deposited over the array of micro-sized diodes 123, where top contact layer 127 may be formed of a transparent conductive oxide (e.g., indium tin oxide (“ITO”)) or a transparent conductive polymer. A protective dielectric layer 129 may then be formed over top contact layer 127 and planarized. Further, coupon 120 may include a backside dielectric layer 125 (e.g., SiO₂ film) located under the array of landing pads 121. In addition, a gap fill layer 128, such as a slot-die coated acrylic or other suitable material, may laterally surround coupon 120 and/or fill the spaces between a plurality of coupons. Optical layer 130 (e.g., transparent polymer, silicon nitride (SiNx), etc.) is an optional layer that may be deposited over coupon 120, where an anti-reflective coating (e.g., silicon dioxide, etc.) may be additionally deposited over optical layer 130. The example of FIG. 1A includes optical layer 130, which may be imprinted to include optical features, such as half ball features 132, where such optical features may act as a micro lens array over the array of micro-sized diodes 123. In addition, bonding layer 134 (e.g., SiO₂) may be located on optical layer 130 to aid in bonding the cover window to the optical layer. Frontplane 110 may also include a black matrix layer to reduce crosstalk between different color regions of the optoelectronic structure.

Backplane 140 can be a CMOS substrate, which may include driving circuitry (e.g., CMOS driving circuitry) or an array of pixel driver chips. In the example of FIG. 1A, backplane 140 includes silicon substrate 143 and driving circuitry 148. In addition, backplane 140 may also include frontside routing layer 147A and backside routing layer 147B. The routing layers may include redistribution lines 146 embedded in dielectric layer 144, where metal redistribution lines 146 may be formed with a damascene process (e.g., single damascene, double damascene, etc.) as part of a single metal layer or multiple metal layers within dielectric layer 144 for routing distribution. Further, optoelectronic structure 100 may also include a substrate (e.g., interposer), such as substrate 200 in FIG. 1A, where solder bumps 204 may be placed on under bump metallization 201 (“UBM”) of backside routing layer 147B to bond backplane 140 to substrate 200 (with optional underfill 202). Backplane 140 may also include a black matrix layer to reduce crosstalk between different color regions of the optoelectronic structure.

In further reference to FIG. 1A, coupon 120 may be directly bonded to backplane 140. In accordance with embodiments, the direct bonding may be wafer-to-wafer or die-to-wafer hybrid bonding using metal-to-metal interconnects (e.g., copper-to-copper) and dielectric-dielectric bonds (e.g. silicon oxide, silicon nitride, silicon carbon nitride, etc.). For example, as illustrated in FIG. 1A, frontplane 110 may include an array of contact vias 111 embedded in a dielectric build-up layer 114, where the array of contact vias 111 may be connected to the array of landing pads 121 of coupon 120. The array of contact vias 111 may be formed with a damascene process (e.g., single damascene, double damascene, etc.) as part of a single metal layer or multiple metal layers within dielectric build-up layer 114 for routing distribution. Following the damascene processing, frontplane 110 may be planarized to form a bonding surface that includes planar dielectric surface 119 and planar contact surface 112. Similarly, backplane 140 may include vias 141 embedded in dielectric layer 144 as part of frontside routing layer 147A. Further, backplane 140 may be planarized to form a bonding surface that includes planar dielectric surface 149 and planarized contact pads 142 on frontside routing layer 147A. In an embodiment, hybrid bonding may be achieved with metal-metal bonds (e.g. copper-copper) between planar contact surfaces 112 of frontplane 110 and planarized contact pads 142 of backplane 140, and with dielectric-dielectric bonds (e.g. silicon oxide, silicon nitride, silicon carbon nitride, etc.) between planar dielectric surface 119 of frontplane 110 and planar dielectric surface 149 of backplane 140, as illustrated in the example of FIG. 1A.

Still referring to FIG. 1A, optoelectronic structure 100 may include cover window 150. Cover window 150 may be formed of any suitable material that protects the display area above the array of micro-sized diodes 123 and allows for the transmission of light to or from the array of micro-sized diodes 123 (e.g., glass, sapphire, etc.). Cover window 150 may be bonded to oxide optical layer 130 through bonding layer 134 by fusion bonding, adhesive bonding, etc. In the example illustrated in FIG. 1A, optoelectronic structure 100 includes bonding layer 154 (e.g. optically clear adhesive) to provide an adhesive bond between the cover window and the optical layer of frontplane 110. In addition, after bonding to optical layer 130, a cavity may be present between optical layer 130 and cover window 150, such as cavity 156 illustrated in FIG. 1A. In further reference to FIG. 1A, the height, h, of cavity 156 may be defined by the distance between top surface 131 of coupon 120 and interior surface 151 of cover window 150. In an embodiment, the height of the cavity may be in the range of 220-260 nm. Cover window 150 may also include an anti-reflective coating (e.g., silicon nitride, tantalum oxide, etc.) on an interior and/or exterior surface to further decrease artifacts caused by reflections onto the backplane. In the example of FIG. 1A, cover window 150 includes anti-reflective coating 158 on interior surface 151. Further, cover window 150 may include an optional opaque coating (e.g., black matrix layer, etc.) on an interior and/or the exterior surface of cover window 150, as well as on one or more side walls of cover window 150 to reduce crosstalk between different color regions of the optoelectronic structure. Further still, cover window 150 may include an anti-static coating (e.g., transparent conductive oxide (TCO), etc.) on an interior and/or exterior surface to prevent static charge buildup that may attract dust and other airborne particles. In another embodiment, the cavity between frontplane 110 and cover window 150 may be filled with a low refractive index spacer. In such instances, the refractive index of the spacer may be in the range of 1.05-1.3.

In another embodiment, the cavity between frontplane 110 and cover window 150 is an air gap. It has been observed that the presence of an air gap between frontplane 110 and cover window 150 may improve light extraction efficiency, reduce artifacts caused by reflections, and minimize absorption losses. However, the integration of the cover window at the die level may present challenges during fabrication (e.g., lack of reproducibility, compromised air gap, etc.). As such, in the embodiments described, the integration of the cover window may occur at the wafer level. In addition, since the integration of the cover window at the wafer level may affect other aspects or components of a micro-LED structure during fabrication, such as localized stresses along the frontplane that may cause warpage of the backplane during backgrinding, the width of the cover window may be controlled to mitigate these localized stresses in the frontplane and still preserve the integrity of the airgap. In some embodiments, where the cover window is attached before backgrinding, the width of the cover window may be approximately the same as the width as the backplane. In other embodiments, where the cover window is attached after backgrinding, the width of the cover window may be less than the width of the backplane. In this way, with the x-y dimensions of the cover window being the same, or in some instances smaller, than the x-y dimensions of the frontplane and backplane, the optoelectronic structures described may allow for a smaller form factor of coupon 120, which may lead to smaller pixels sizes and/or greater flexibility in optimizing pixel design.

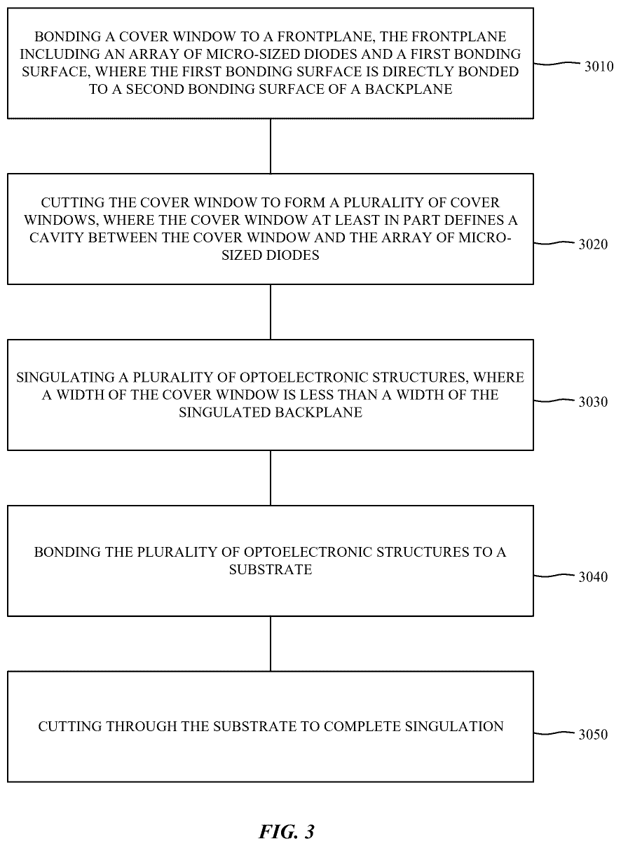

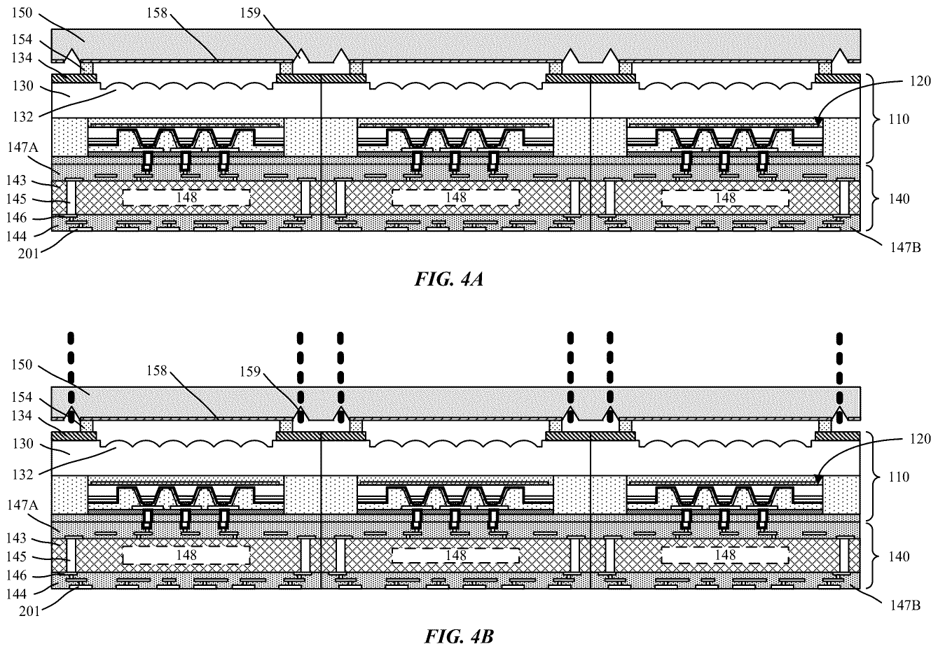

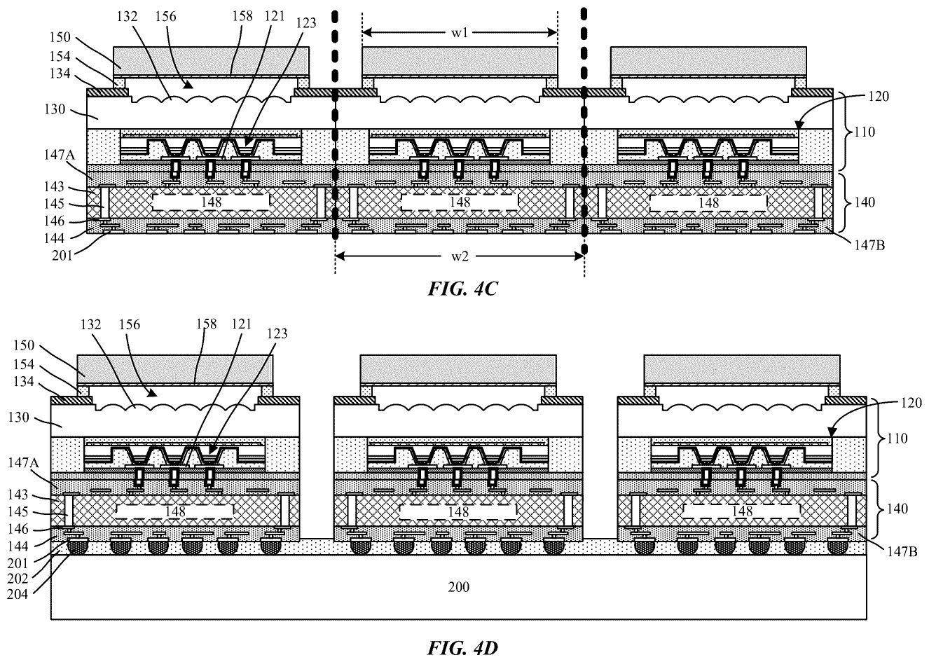

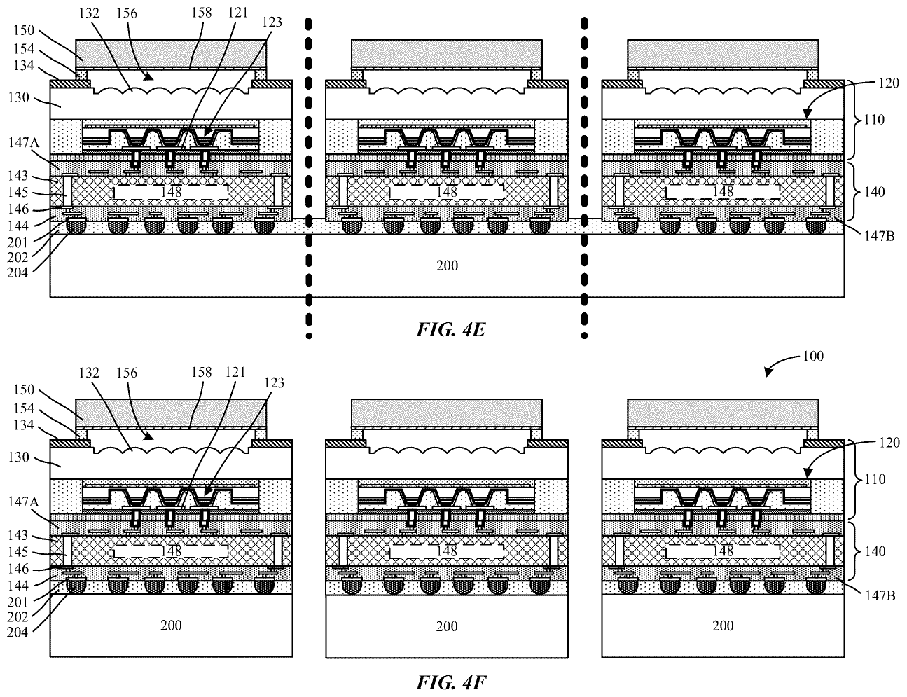

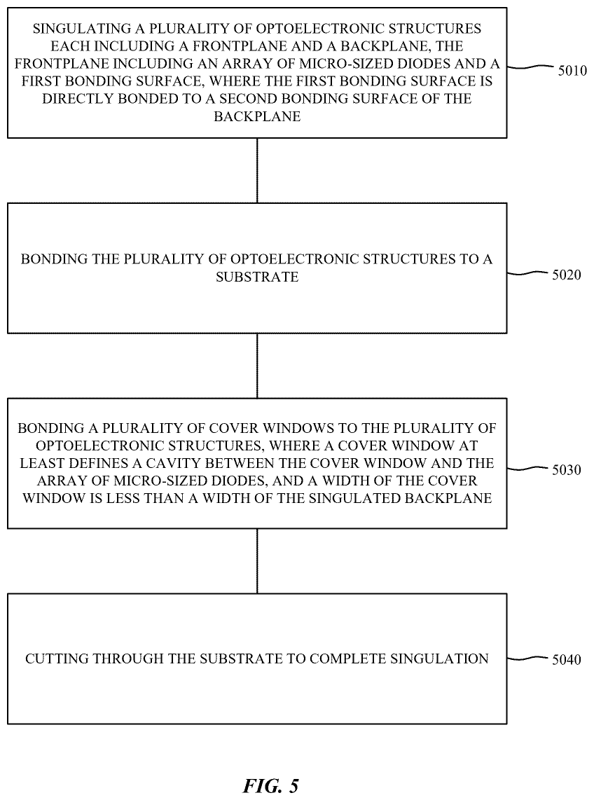

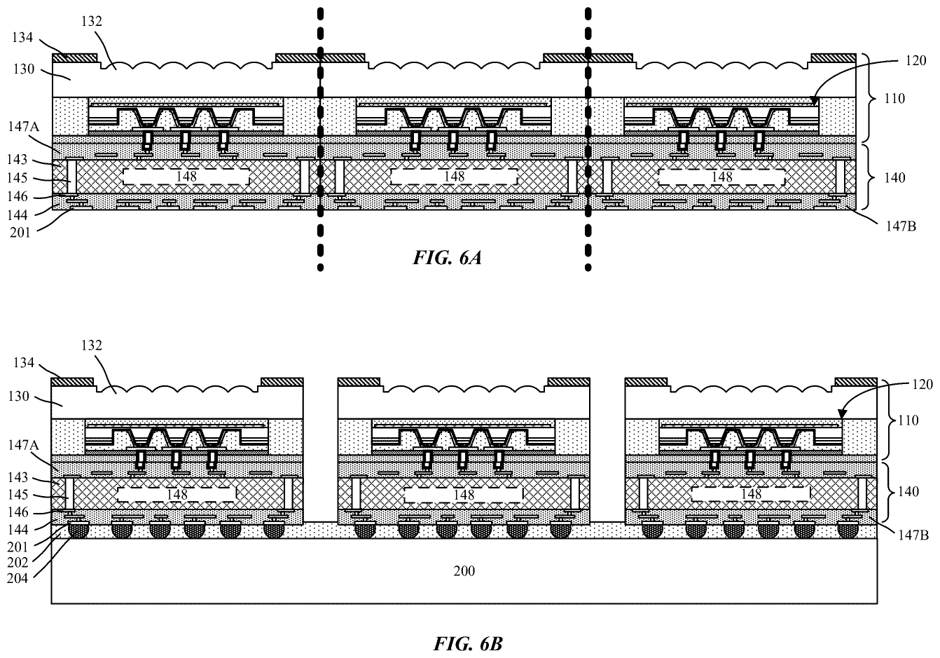

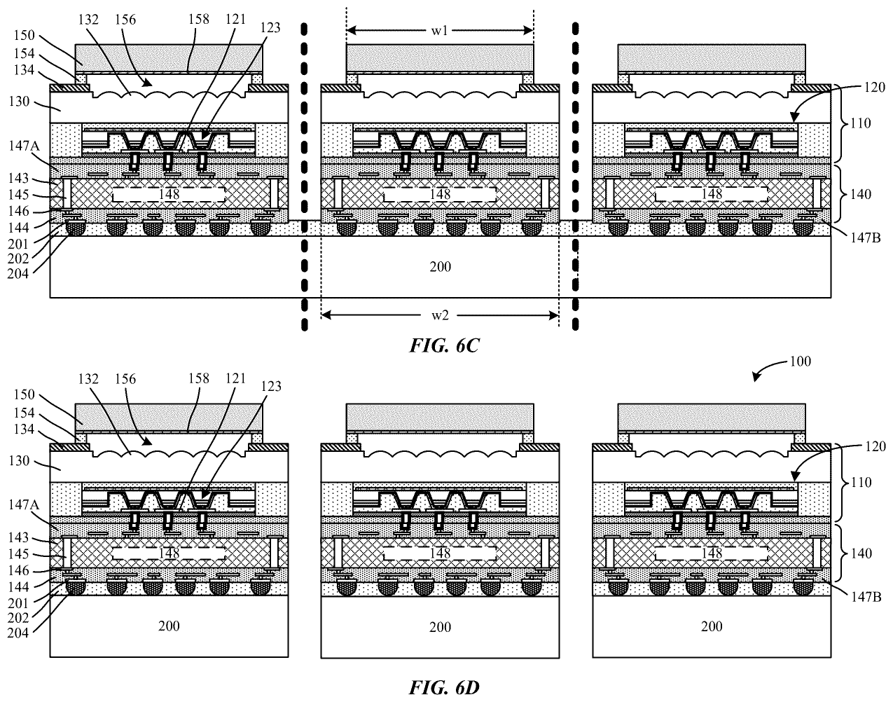

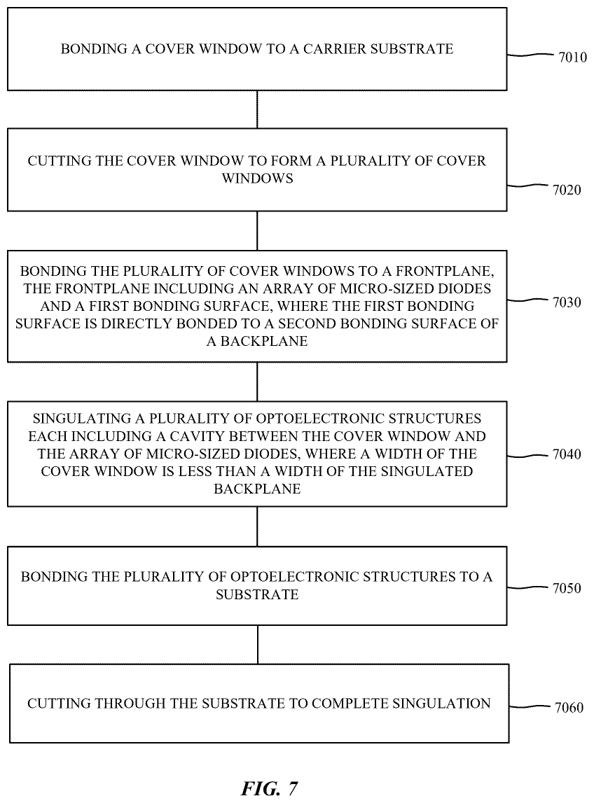

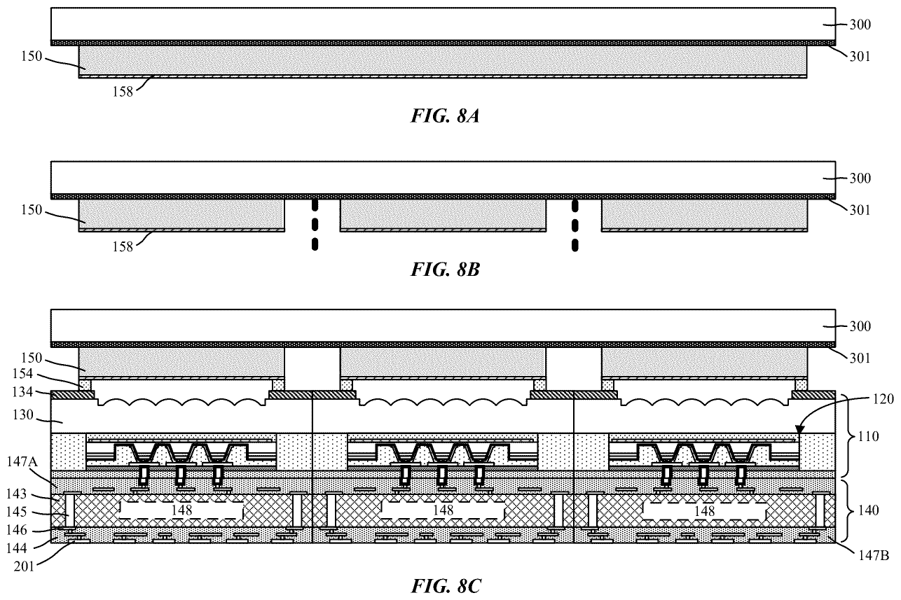

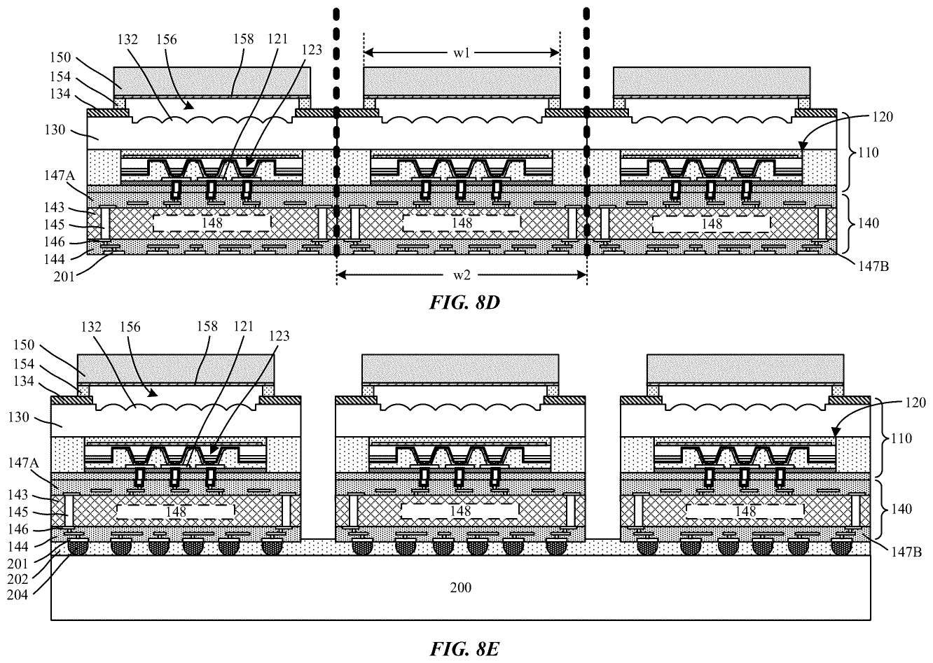

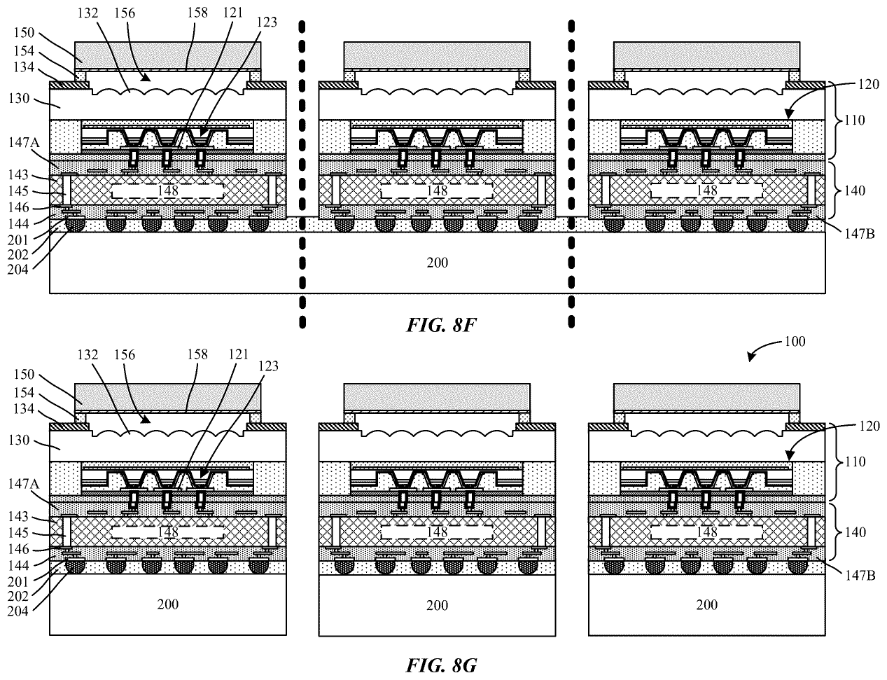

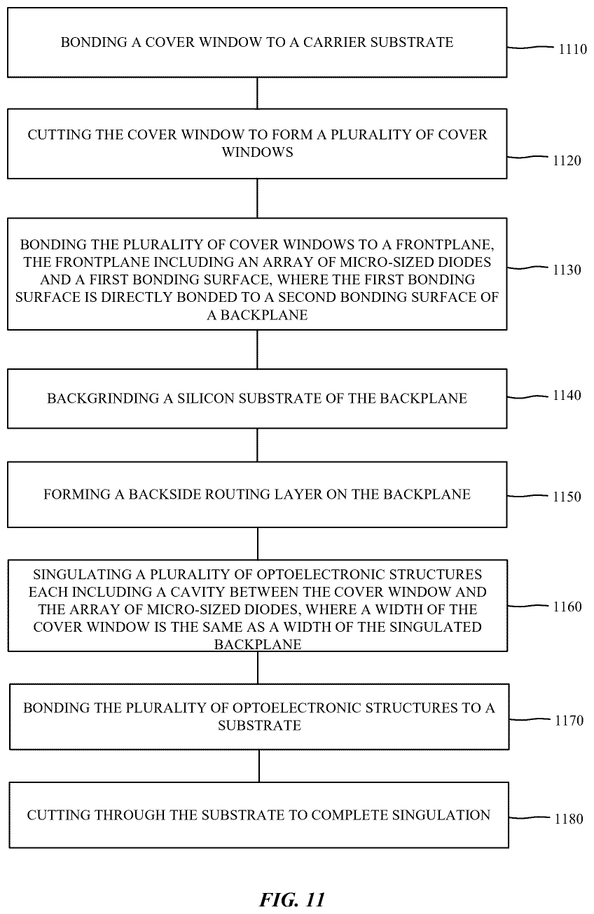

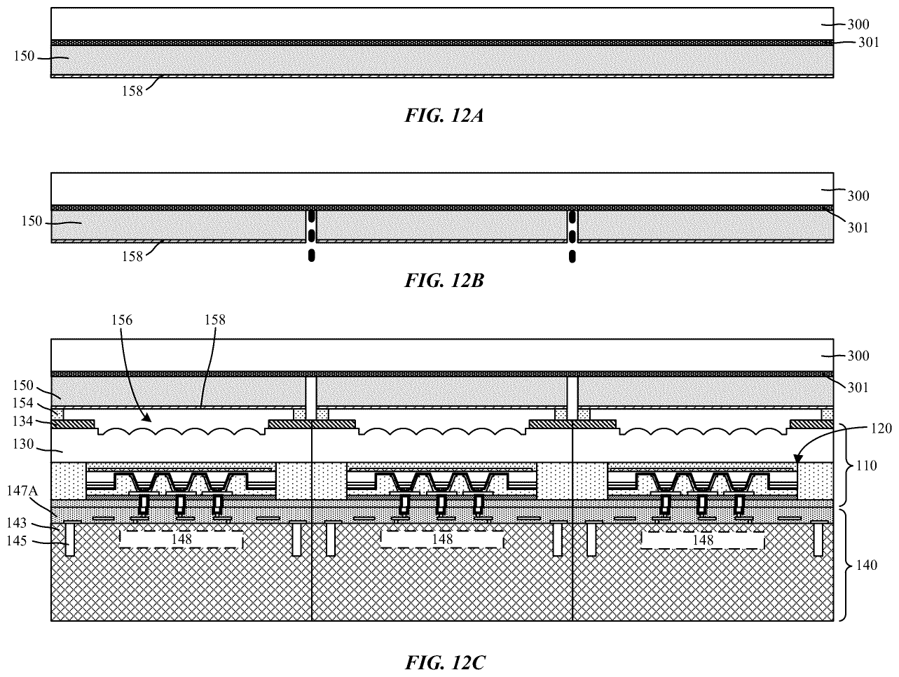

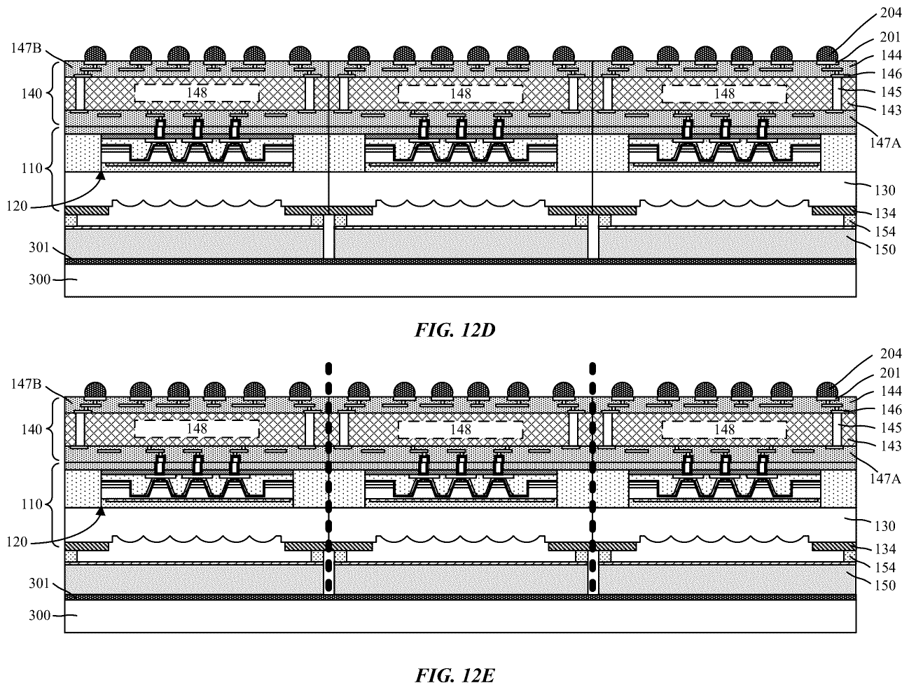

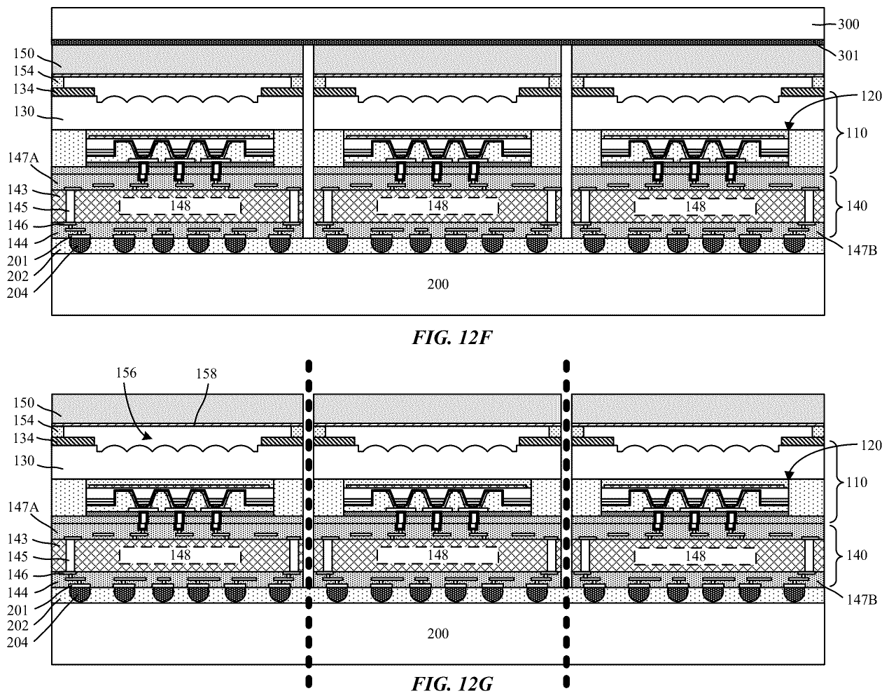

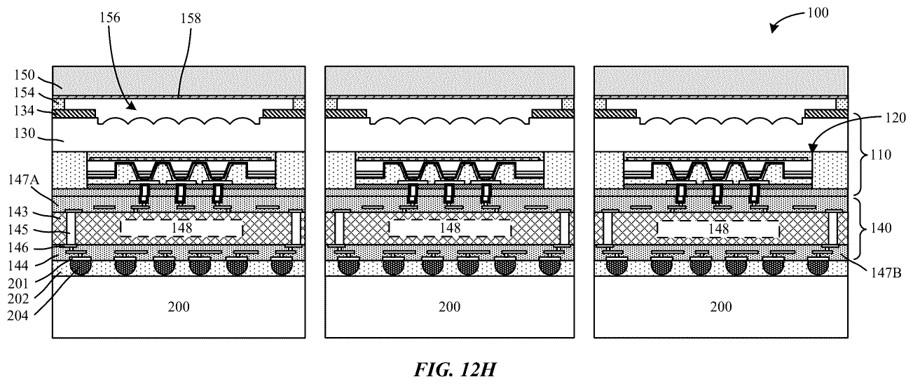

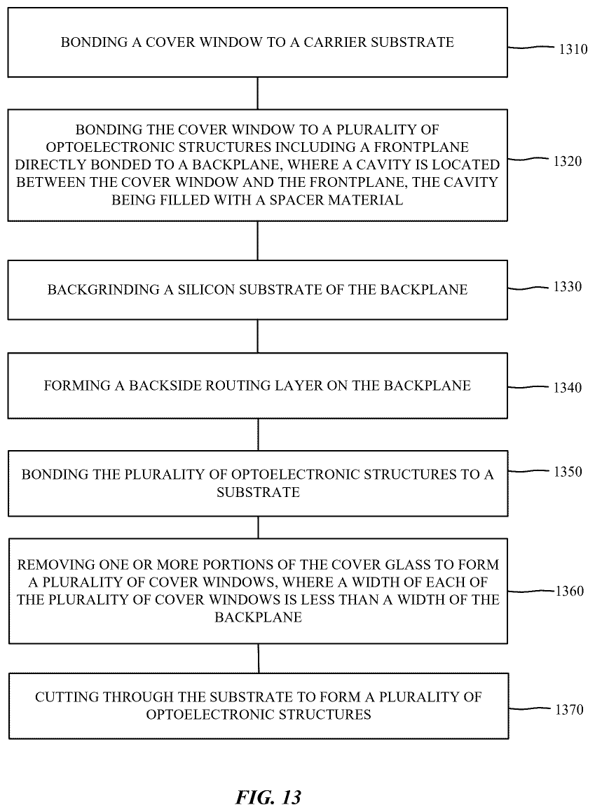

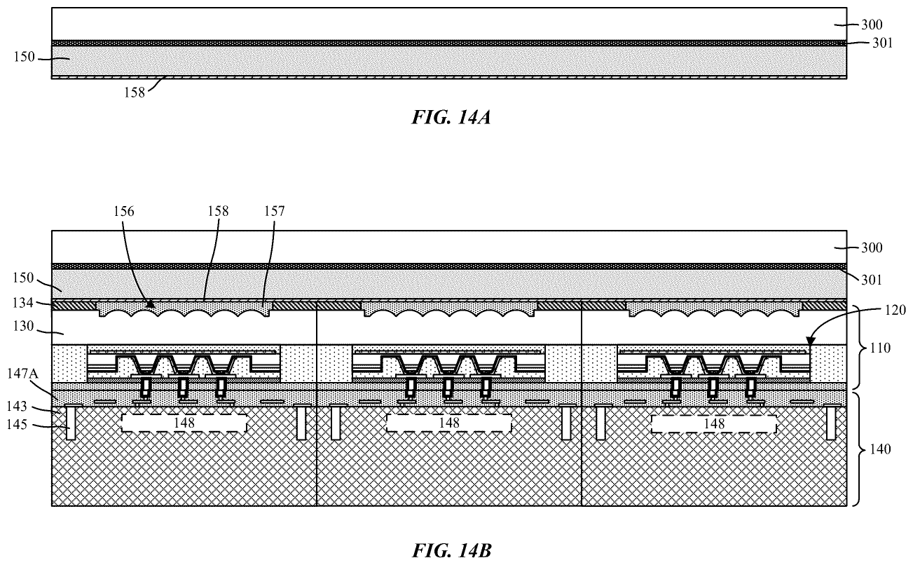

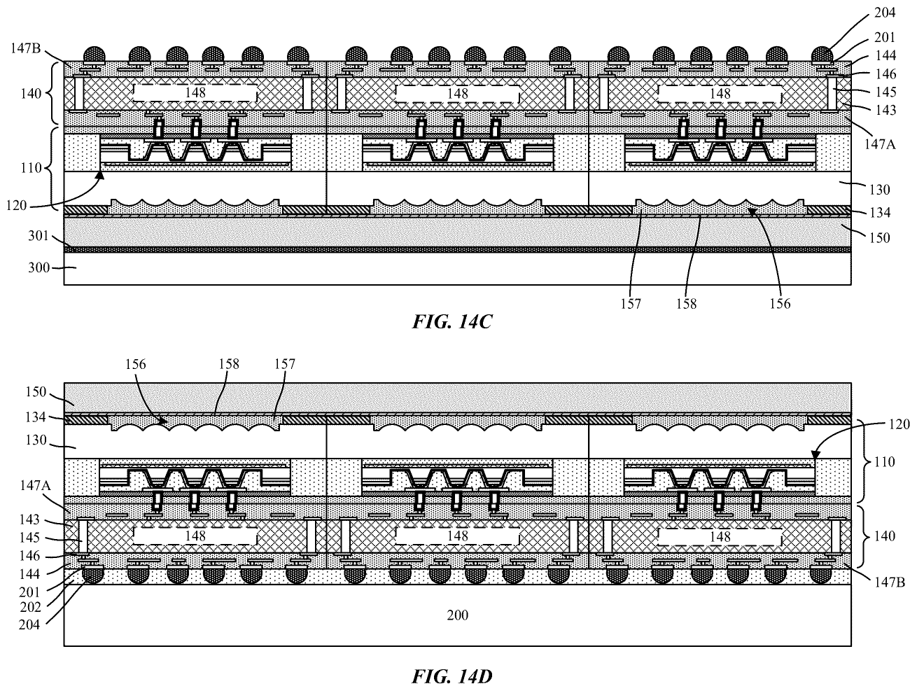

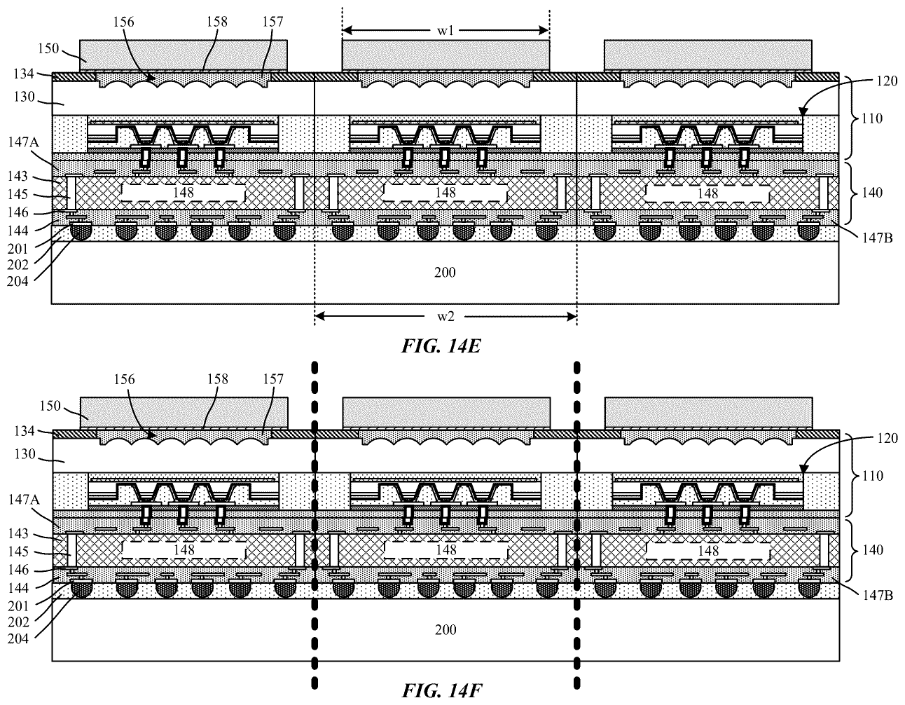

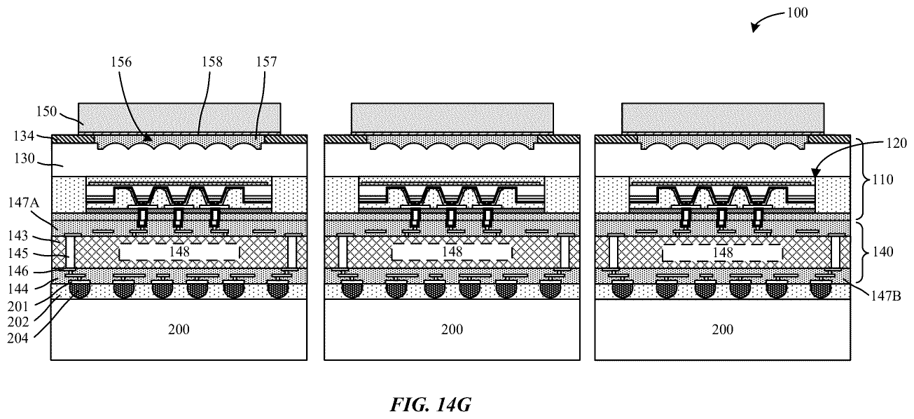

Referring now to FIG. 1B, a cross-sectional side view illustration is provided of an optoelectronic structure in accordance with an embodiment. The embodiment described in FIG. 1B is substantially similar to the embodiment described in FIG. 1A except for the width of cover window 150. For example, the width of cover window 150 in FIG. 1A, w1, is less than the width of frontplane 110 and backplane 140, w2, whereas the width of cover window 150 in FIG. 1B, w2, is the same as the width of frontplane 110 and backplane 140. The different widths of cover window 150 relate to the methods of assembly for each embodiment. For example, during fabrication of optoelectronic structure 100, a backgrinding operation may be performed on backplane 140 to grind silicon substrate 143 and expose through-silicon vias 145. In one example, backplane 140 may have a thickness of approximately 775 μm before backgrinding and a thickness of approximately 50 μm after backgrinding. In instances where the cover window is attached before backgrinding, the width of the cover window may be the same as the width of the backplane, as illustrated in FIG. 1B. In instances where the cover window is attached after backgrinding, the width of the cover window may be less than the width of the backplane, as illustrated in FIG. 1A. As such, it should be noted that the methods described in FIG. 3 and FIGS. 4A-4F, FIG. 5 and FIGS. 6A-6D, and FIG. 7, FIGS. 8A-8F, and FIG. 9 and FIGS. 10A-10F relate to the optoelectronic structure in FIG. 1A in which the cover window is attached after backgrinding, whereas the methods described in FIG. 11 and FIGS. 12A-12H, and FIG. 13 and FIGS. 14A-14G relate to the optoelectronic structure in FIG. 1B in which the cover window is attached before backgrinding.

Referring now to FIGS. 1C-1D, FIG. 1C is a cross-sectional side view illustration of multiple optoelectronic structures each including a cover window in accordance with an embodiment; FIG. 1D is a cross-sectional side view illustration of multiple optoelectronic structures including a cover window that spans over the multiple optoelectronic structures in accordance with an embodiment. The embodiments described in FIG. 1C-1D are substantially similar to the embodiments described in FIGS. 1A-1B, where optoelectronic structure 100 has been configured to include a singular coupon 120. However, in the embodiments described in FIGS. 1C-1D, optoelectronic structure 100 has been configured to include multiple coupons 120. In such multi-panel configurations, such as the two-panel configurations illustrated in FIGS. 1C-1D, the multiple panels may be connected along the short side or the long side. Further, such multi-panel configurations may include individual cover windows for each panel, a single cover window spanning multiple panels, or no cover windows. In one example, optoelectronic structure 100 may include multiple cover windows 150 for each of the multiple coupons 120, as illustrated in FIG. 1C. In another example, optoelectronic structure 100 may include a singular cover window 150 that spans over multiple coupons (or multiple arrays of micro-sized diodes 123) as illustrated in FIG. 1D, where cover window 150 has a width, w3. It should be noted that the above illustrations and descriptions are merely illustrative, not exhaustive, and that other variations or combinations of such embodiments are contemplated. For example, an embodiment may include more than the two coupons 120 illustrated in FIG. 1C-1D, where such an embodiment may include both a cover window that spans over a single coupon as well as a cover window that spans over multiple coupons. In other embodiments still, cover window 150 may include chamfered edges, such as chamfered edge 175 illustrated in FIG. 1E. The chamfered edges may be formed with bevel cuts by any conventional glass processing technique (e.g., blade sawing, laser cutting, grinding, etc.) at any suitable angle relative to the top surface of the cover window to facilitate optical coupling, reduce edge reflections, etc.

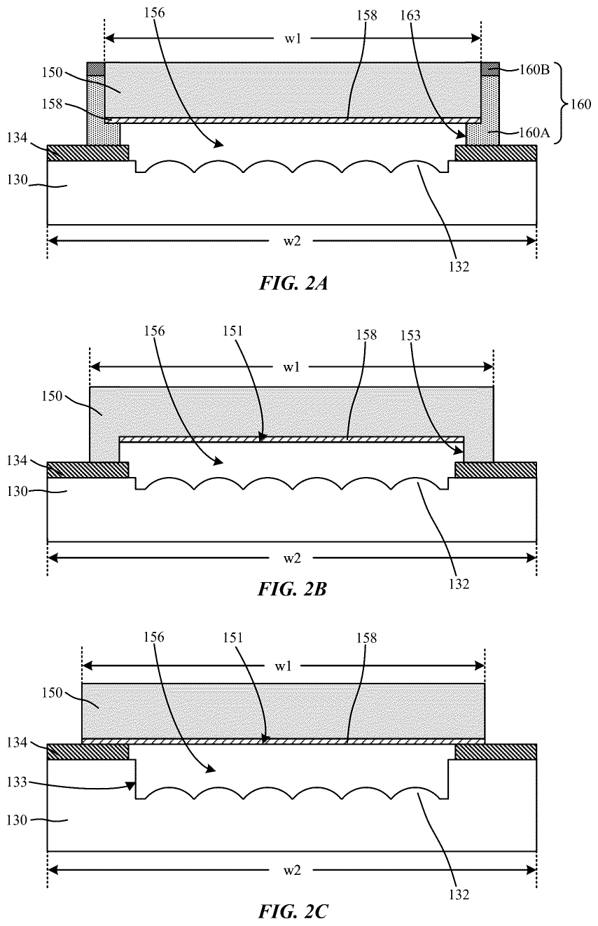

Referring now to FIGS. 2A-2C, FIG. 2A is a cross-sectional side view illustration of a cover window embedded within a frame structure in accordance with an embodiment; FIG. 2B is a cross-sectional side view illustration of a recessed cover window in accordance with an embodiment; and FIG. 2C is a cross-sectional side view illustration of a recessed optical layer in accordance with an embodiment. In embodiments, the cavity may be defined based on how the cover window attaches to optical layer 130. For example, in reference to FIG. 2A, cover window 150 may be embedded within a frame structure, where the frame structure may be bonded to the optional optical layer. In such instances, a first frame structure may be formed (e.g., injection molding, compression molding, etc.), the cover window may be placed within the first frame structure, followed by formation of a second framed structure to serve a capping layer that retains the cover window within the frame structure, where the first frame structure and the second frame structure may be the same material. For example, in reference to FIG. 2A, cover window 150 is embedded within frame structure 160, which includes first frame structure 160A and second frame structure 160B. Further, cavity 156 may be defined at least in part by sidewall 163 of frame structure 160, where sidewall 163 laterally surrounds cavity 156. In reference to FIG. 2B, cover window 150 may include a recess that, at least in part, defines cavity 156. In such instances, the cover window may be patterned by any suitable method (e.g., dry etch, etc.) and then bonded to the optical layer (e.g., oxide-oxide fusion bond, Au—Sn eutectic bond, Au—Au compression bond, etc.). For example, in reference to FIG. 2B, cover window 150 includes a recess with sidewall 153 and interior surface 151, where cover window 150 may be bonded to bonding layer 134 of optical layer 130. Further, cavity 156 may be defined at least in part by sidewall 153 of cover window 150, where sidewall 153 laterally surrounds cavity 156. In reference to FIG. 2C, optical layer 130 may include a recess that at least in part defines cavity 156. In such instances, the optical may be patterned and etched to form the recess. For example, in reference to FIG. 2C, optical layer 130 includes a recess with sidewall 133, where cover window 150 may be bonded to bonding layer 134 of optical layer 130 (e.g., fusion bond). Further cavity 156 may be defined at least in part by sidewall 133 of optical layer 130, where sidewall 133 laterally surrounds cavity 156. It should be noted that the above illustrations and descriptions are merely illustrative, not exhaustive, and that other variations or combinations of such embodiments are contemplated. For example, an embodiment may include both the recessed cover window described in FIG. 2B and the recessed optical layer described in FIG. 2C, as well as other combinations or variations. In addition, the embodiments described in FIGS. 2A-2C show cover window 150 that includes a width, w1, that is less than the width of the backplane, w2, similar to the embodiment described in FIG. 1A. However, the embodiments described in FIGS. 2A-2C may also apply where the width of the cover window is the same as the width of the backplane, similar to the embodiment described in FIG. 1B.

Referring now to FIG. 3 and FIGS. 4A-4F, FIG. 3 is a flow chart and FIGS. 4A-4F are schematic cross-sectional side view illustrations of a method for assembling an optoelectronic structure in accordance with an embodiment. In the interest of clarity and conciseness, the method of FIG. 3 is described concurrently with the illustrations of FIGS. 4A-4F. At operation 3010, FIG. 4A shows cover window 150 bonded to frontplane 110, where cover window 150 spans over a plurality of optoelectronic structures. In some embodiments, cover window 150 may be directly bonded to frontplane 110 (e.g., wafer-to-wafer fusion bonded). In other embodiments, cover window 150 may be bonded to frontplane 110 by a bonding layer (e.g., optically clear adhesive, etc.), such as bonding layer 154 as illustrated in the example of FIG. 4A. Further, in the example of FIG. 4A, cover window 150 includes multiple “pre-cuts,” such as pre-cut 159, to aid in cutting the cover window to a desired width. In addition, coupons 120 may be directly bonded (e.g., hybrid bonded) to backplane 140, where frontplane 110 includes both coupon 120 and optional optical layer 130, similar to the embodiment described in FIG. 1A. It should be noted that, in the embodiment described here, backplane 140 includes frontside routing layer 147A, through-silicon vias 145 and backside routing layer 147B, where the operations of backgrinding silicon substrate 143 to expose through-silicon vias 145 and forming backside routing layer 147B were performed before attaching cover window 150 to frontplane 110 at operation 3010. In this way, since cover window 150 is attached to frontplane 110 after the backgrinding operation, cover window 150 may be cut to a width that is less than a width of backplane 140. As such, in FIG. 4B operation 3020 shows cover window 150 cut from the top (with the loose glass removed) to form a plurality of cover windows. Further, the optoelectronic structure includes a cavity between cover window 150 and optical layer 130, such as cavity 156, where the cavity may be defined at least in part by any combination of its surrounding structures, similar to the examples described in FIGS. 2A-2C (e.g., frame structure, recessed cover window, recessed optical window, etc.). In an embodiment, cavity 156 is an air gap. As illustrated in FIG. 4C, after cutting through pre-cuts 159, cover window 150 has a width, w1, that is less than a width, w2, of backplane 140. In further reference to FIG. 4C, at operation 3030 frontplane 110 and backplane 140 may be singulated to form a plurality of optoelectronic structures, similar to optoelectronic structure 100 illustrated in FIG. 1A. At operation 3040, solder bumps 204 may be placed on UBM 201 of backside routing layer 147B for each of the plurality of optoelectronic structures for bonding to substrate 200 (e.g., reflow, laser assisted bonding, etc.), as illustrated in FIG. 4D. In some instances, underfill 202 may be applied at operation 3040 to improve the bonding strength of the plurality of optoelectronic structures to substrate 200. Such bonding may be followed by a cutting operation through substrate 200 at operation 3050 to complete singulation of the optoelectronic structures, as illustrated in FIGS. 4E-4F, respectively.

Referring now to FIG. 5 and FIGS. 6A-6D, FIG. 5 is a flow chart and FIGS. 6A-6D are schematic cross-sectional side view illustrations of a method for assembling an optoelectronic package in accordance with an embodiment. In the interest of clarity and conciseness, the method of FIG. 5 is described concurrently with the illustrations of FIGS. 6A-6D. At operation 5010, frontplane 110 and backplane 140 may be singulated to form a plurality of optoelectronic structures as illustrated in FIG. 6A. In such instances, backplane 140 may be directly bonded (e.g., hybrid bonded) to frontplane 110, where frontplane 110 includes coupon 120 and optical layer 130, similar to the embodiment described in FIG. 1A. At operation 5020, solder bumps 204 may be placed on UBM 201 of backside routing layer 147B for each of the plurality of optoelectronic structures for bonding to substrate 200 (e.g., reflow, laser assisted bonding, etc.), as illustrated in FIG. 6B. In some instances, underfill 202 may be applied at operation 5020 to improve the bonding strength of the plurality of optoelectronic structures to substrate 200. In FIG. 6C, at operation 5030 a plurality of cover windows, such as cover window 150, may be bonded to the plurality of optoelectronic structures by bonding layer 154 (e.g., adhesive bond, fusion bond, etc.). In some embodiments, cover window 150 may be directly bonded to frontplane 110 (e.g., wafer-to-wafer fusion bonded). It should be noted that, in the embodiment described here, backplane 140 includes frontside routing layer 147A, through-silicon vias 145 and backside routing layer 147B, where the operations of backgrinding silicon substrate 143 to expose through-silicon vias 145 and forming backside routing layer 147B were performed before attaching cover window 150 to frontplane 110 at operation 5030. In this way, since cover window 150 is attached to frontplane 110 after the backgrinding operation, cover window 150 may have a width that is less than the width of backplane 140. For example, in FIG. 6C, cover window 150 has a width, w1, and backplane 140 has a width, w2, where w1 is less than w2. Further, the optoelectronic structure includes a cavity between cover window 150 and optical layer 130, such as cavity 156, where the cavity may be defined at least in part by any combination of its surrounding structures, similar to the examples described in FIGS. 2A-2C (e.g., frame structure, recessed cover window, recessed optical layer, etc.). In an embodiment, cavity 156 is an air gap. Further, at operation 5040 a cutting operation may be performed through substrate 200 to complete singulation of optoelectronic structures 100, as illustrated in FIG. 6D.

Referring now to FIG. 7 and FIGS. 8A-8G, FIG. 7 is a flow chart and FIGS. 8A-8G are schematic cross-sectional side view illustrations of a method for assembling an optoelectronic structure in accordance with an embodiment. In the interest of clarity and conciseness, the method of FIG. 7 is described concurrently with the illustrations of FIGS. 8A-8G. At operation 7010, cover window 150 may be bonded to carrier substrate 300 by temporary adhesive 301, where cover window 150 may then be cut to form a plurality of cover windows at operation 7020, as illustrated in FIG. 8A and FIG. 8B, respectively. Referring to FIG. 8C, at operation 7030 the plurality of cover windows may be bonded to frontplane 110. In some embodiments, cover window 150 may be directly bonded to frontplane 110 (e.g., wafer-to-wafer fusion bonded). In other embodiments, cover window 150 may be bonded to frontplane 110 by a bonding layer (e.g., optically clear adhesive, etc.), such as bonding layer 154 as illustrated in the example of FIG. 8C. In addition, coupons 120 may be directly bonded (e.g., hybrid bonded) to backplane 140, where frontplane 110 includes both coupon 120 and optional optical layer 130, similar to the embodiment described in FIG. 1A. It should be noted that, in the embodiment described here, backplane 140 includes frontside routing layer 147A, through-silicon vias 145 and backside routing layer 147B, where the operations of backgrinding silicon substrate 143 to expose through-silicon vias 145 and forming backside routing layer 147B were performed before attaching cover window 150 to frontplane 110 at operation 7030. In this way, since cover window 150 is attached to frontplane 110 after the backgrinding operation, cover window 150 may have a width that is less than a width of backplane 140. As such, FIG. 8D shows cover window 150 has a width, w1, and backplane 140 has a width, w2, where w1 is less than w2. Further, the optoelectronic structure includes a cavity between cover window 150 and optical layer 130, such as cavity 156, where the cavity may be defined at least in part by any combination of its surrounding structures, similar to the examples described in FIGS. 2A-2C (e.g., frame structure, recessed cover window, recessed optical layer, etc.). In an embodiment, cavity 156 is an air gap. In further reference to FIG. 8D, at operation 7040 frontplane 110 and backplane 140 may be singulated to form a plurality of optoelectronic structures, similar to optoelectronic structure 100 illustrated in FIG. 1A. Further, at operation 7050, solder bumps 204 may be placed on UBM 201 of backside routing layer 147B for each of the plurality of optoelectronic structures for bonding to substrate 200 (e.g., reflow, laser assisted bonding, etc.), as illustrated in FIG. 8E. In some instances, underfill 202 may be applied at operation 7050 to improve the bonding strength of the plurality of optoelectronic structures to substrate 200. Such bonding may be followed by a cutting operation through substrate 200 at operation 7060 to complete singulation of the optoelectronic structures, as illustrated in FIGS. 8F-8G, respectively.

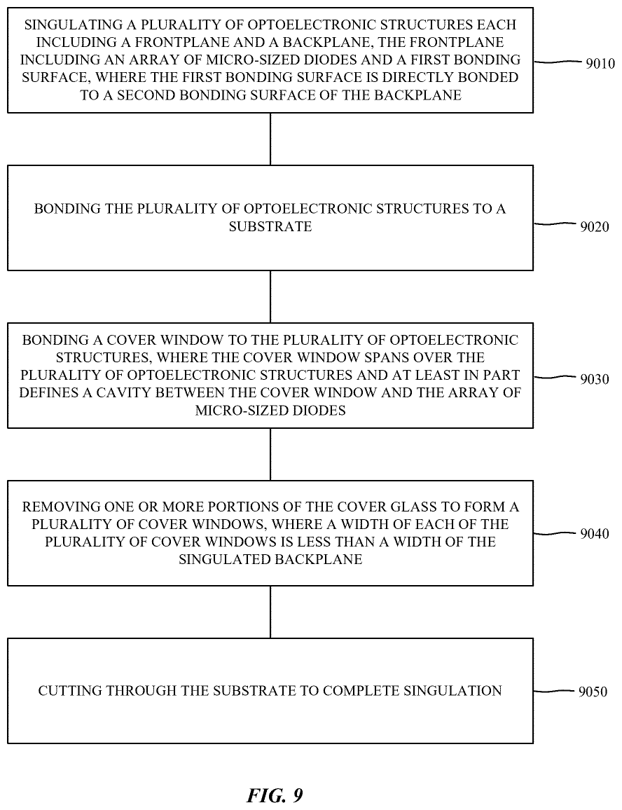

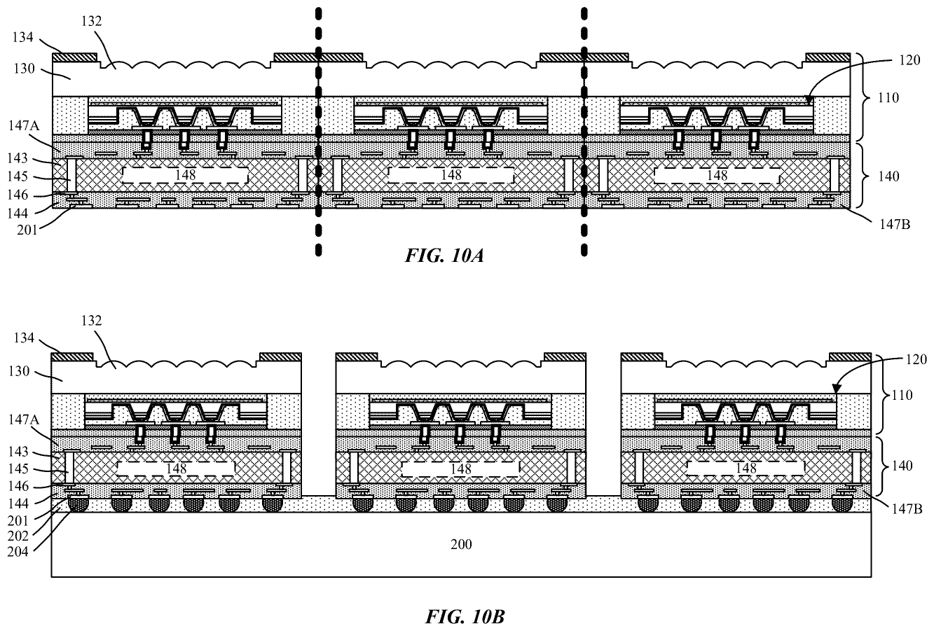

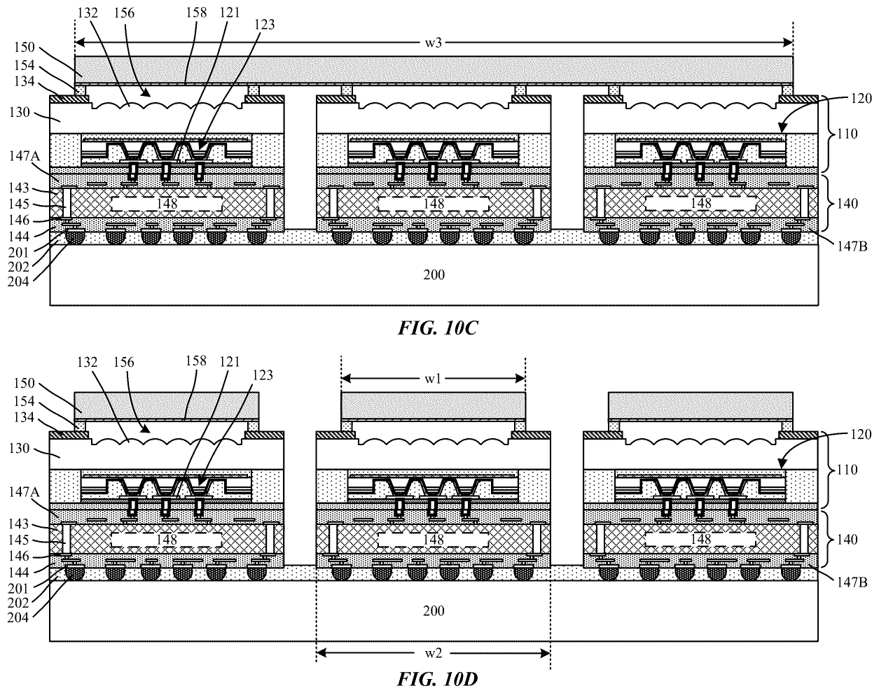

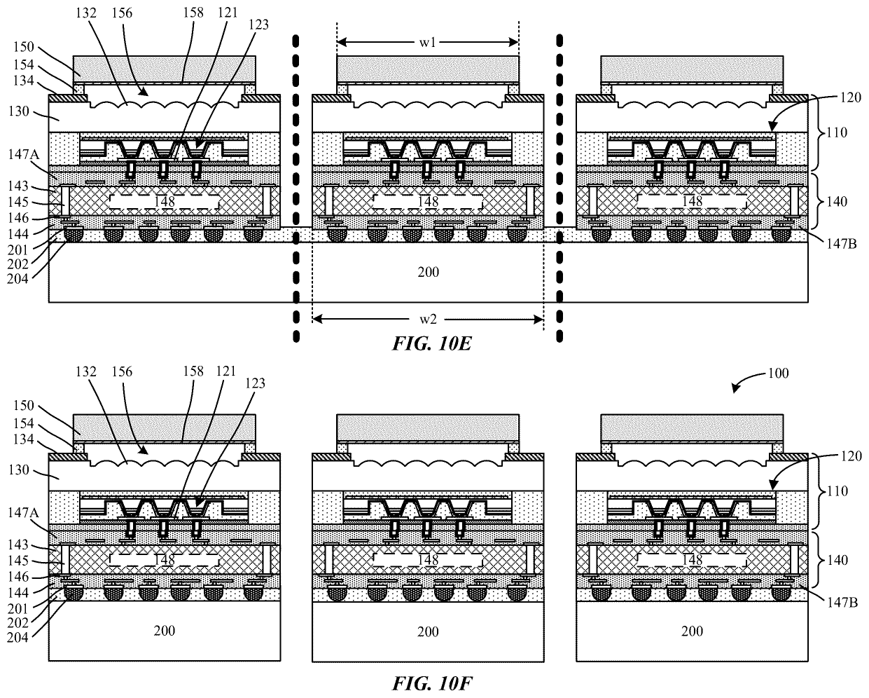

Referring now to FIG. 9 and FIGS. 10A-10F, FIG. 9 is a flow chart and FIGS. 10A-10F are schematic cross-sectional side view illustrations of a method for assembling an electronic package in accordance with an embodiment. In the interest of clarity and conciseness, the method of FIG. 9 is described concurrently with the illustrations of FIGS. 10A-10F. At operation 9010, frontplane 110 and backplane 140 may be singulated to form a plurality of optoelectronic structures as illustrated in FIG. 10A. In such instances, backplane 140 may be directly bonded (e.g., hybrid bonded) to frontplane 110, where frontplane 110 includes coupon 120 and optical layer 130, similar to the embodiment described in FIG. 1A. At operation 9020, solder bumps 204 may be placed on UBM 201 of backside routing layer 147B for each of the plurality of optoelectronic structures for bonding to substrate 200 (e.g., reflow, laser assisted bonding, etc.), as illustrated in FIG. 10B. In some instances, underfill 202 may be applied at operation 9020 to improve the bonding strength of the plurality of optoelectronic structures to substrate 200. In FIG. 10C, at operation 9030 a cover window, such as cover window 150, may be bonded to the plurality of optoelectronic structures, where the cover window spans over the plurality of optoelectronic structures. In some embodiments, cover window 150 may be bonded to frontplane 110 by bonding layer 154 (e.g., adhesive bond, fusion bond, etc.), as illustrated in FIG. 10C. In other embodiments, cover window 150 may be directly bonded to frontplane 110 (e.g., wafer-to-wafer fusion bonded).

It should be noted that, in the embodiment described here, backplane 140 includes frontside routing layer 147A, through-silicon vias 145 and backside routing layer 147B, where the operations of backgrinding silicon substrate 143 to expose through-silicon vias 145 and forming backside routing layer 147B were performed before attaching cover window 150 to frontplane 110 at operation 9030. In this way, since cover window 150 is attached to frontplane 110 after the backgrinding operation, cover window 150 may have a width that is less than the width of backplane 140. As such, at operation 9040 portions of cover window 150 may be removed by wet etching (or any other suitable method) to form a plurality of cover windows 150, as illustrated in FIG. 10D. In further reference to FIG. 10D, cover window 150 has a width, w1, and backplane 140 has a width, w2, where w1 is less than w2. Further, the optoelectronic structure may include a cavity between cover window 150 and optical layer 130, such as cavity 156, where the cavity may be defined at least in part by any combination of its surrounding structures, similar to the examples described in FIGS. 2A-2C (e.g., frame structure, recessed cover window, recessed optical layer, etc.). In an embodiment, cavity 156 is an air gap. Further, at operation 9050, FIG. 10E shows a cutting operation through substrate 200 to complete singulation and form a plurality of optoelectronic structures 100, as illustrated in FIG. 10F.

Referring now to FIG. 11 and FIGS. 12A-12H, FIG. 11 is a flow chart and FIGS. 12A-12H are schematic cross-sectional side view illustrations of a method for assembling an electronic package in accordance with an embodiment. In the interest of clarity and conciseness, the method of FIG. 11 is described concurrently with the illustrations of FIGS. 12A-12H. At operation 1110, cover window 150 may be bonded to carrier substrate 300 by temporary adhesive 301, where cover window 150 may then be cut to form a plurality of cover windows at operation 1120, as illustrated in FIG. 12A and FIG. 12B, respectively. Referring to FIG. 12C, at operation 1130 the plurality of cover windows may be bonded to frontplane 110, where frontplane 110 may include optical layer 130 and coupons 120 directly bonded to backplane 140, similar to the example described in FIG. 1B. In some embodiments, cover window 150 may be directly bonded to frontplane 110 (e.g., wafer-to-wafer fusion bonded). In other embodiments, cover window 150 may be bonded to frontplane 110 by a bonding layer (e.g., optically clear adhesive, etc.), such as bonding layer 154 as illustrated in the example of FIG. 12C. Further, the optoelectronic structure includes a cavity between cover window 150 and optical layer 130, such as cavity 156, where the cavity may be defined at least in part by any combination of its surrounding structures, similar to the examples described in FIGS. 2A-2C (e.g., frame structure, recessed cover window, recessed optical layer, etc.). In an embodiment, cavity 156 is an air gap.

It should be noted that, in the embodiment described here, the bonding of cover window 150 to frontplane 110 occurs before the backgrinding operation and formation of backside routing layer 147B. In such instances, the width of cover window 150 may approximately the same as the width of the backplane to reduce the localized stresses in the frontplane during backgrinding and aid in preventing warpage of the backplane, similar to the embodiment described in FIG. 1B. Further, at operation 1140 a backgrinding operation may be performed on silicon substrate 143 to reveal through-silicon vias 145 followed by the formation of backside routing layer 147B at operation 1150, as illustrated in FIG. 12D. In such instances, backside routing layer 147B may be formed by a damascene process to embed metal redistribution lines 146 within dielectric layer 144, as well as forming UBM 201 and placing solder bumps 204 on UBM 201. Referring now to FIG. 12E, at operation 1160 frontplane 110 and backplane 140 may be singulated to form a plurality of optoelectronic structures similar to optoelectronic structure 100 illustrated in FIG. 1B. In some embodiments, singulating the plurality of optoelectronic structures does not include cutting through carrier substrate 300. In such instances, carrier substrate 300 may be flipped so that the plurality of optoelectronic structures may be bonded to substrate 200 while still attached to carrier substrate 300 as illustrated in FIG. 12F, where carrier substrate 300 may then be removed at operation 1170. In other embodiments, singulating the plurality of optoelectronic structures includes cutting through carrier substrate 300, where the plurality of optoelectronic structures (each including diced carrier substrates) may be transferred and bonded to substrate 200 (e.g., pick and place), followed by removal of the diced carrier substrates. In some instances, after the bonding of the plurality of optoelectronic structures to substrate 200 (e.g., reflow, laser assisted bonding, etc.), underfill 202 may be applied to improve bonding strength. Such bonding may then be followed by a cutting operation through substrate 200 at operation 1180 to complete singulation of the optoelectronic structures, as illustrated in FIGS. 12G-12H, respectively.

Referring now to FIG. 13 and FIGS. 14A-14F, FIG. 13 is a flow chart and FIGS. 14A-14F are schematic cross-sectional side view illustrations of a method for assembling an electronic package in accordance with an embodiment. In the interest of clarity and conciseness, the method of FIG. 13 is described concurrently with the illustrations of FIGS. 14A-14F. At operation 1310, FIG. 14A shows cover window 150 bonded to carrier substrate 300 by temporary adhesive 301. At operation 1320, FIG. 14B shows cover window 150 bonded to frontplane 110, where frontplane may include optical layer 130 and coupons 120 directly bonded (e.g., hybrid bonded) to backplane 140. In some embodiments, cover window 150 may be directly bonded to frontplane 110 (e.g., wafer-to-wafer fusion bonded) as illustrated in the example of FIG. 14B. In other embodiments, cover window 150 may be bonded to frontplane 110 by a bonding layer (e.g., optically clear adhesive, etc.). Further, the optoelectronic structure includes a cavity between cover window 150 and optical layer 130, such as cavity 156, where the cavity may be defined at least in part by any combination of its surrounding structures, similar to the examples described in FIGS. 2A-2C (e.g., frame structure, recessed cover window, recessed optical layer, etc.). In an embodiment, cavity 156 may include a low refractive index spacer material, such as spacer 157 illustrated in FIG. 14B. In such instances, the refractive index of the spacer material may be in the range of 1.05-1.3.

It should be noted that, in the embodiment described here, the bonding of cover window 150 to frontplane 110 occurs before the backgrinding operation and formation of backside routing layer 147B. In such instances, the width of cover window 150 may approximately the same as the width of the backplane during backgrinding to reduce the localized stresses in the frontplane and aid in preventing warpage of the backplane, similar to the embodiment described in FIG. 1B. In addition, the low refractive index spacer (e.g., spacer 157) further aids in reducing the localized stresses in the frontplane by absorbing such stresses during the backgrinding operation. Referring now to FIG. 14C, at operation 1330 a backgrinding operation may be performed on silicon substrate 143 to reveal through-silicon vias 145 followed by the formation of backside routing layer 147B at operation 1340. In such instances, backside routing layer 147B may be formed by a damascene process to embed metal redistribution lines 146 within dielectric layer 144, as well as forming UBM 201 and placing solder bumps 204 on UBM 201. At operation 1350, FIG. 14D shows carrier substrate 300 flipped so that the plurality of optoelectronic structures may be bonded to substrate 200, where carrier substrate 300 may then be removed after bonding the plurality of optoelectronic structures to substrate 200. In some instances, after the bonding of the plurality of optoelectronic structures to substrate 200 (e.g., reflow, laser assisted bonding, etc.), underfill 202 may be applied to improve bonding strength. At operation 1360, FIG. 14E shows where portions of cover window 150 may be removed by wet etching (or any other suitable method) to form a plurality of cover windows 150. In such instances where removal of portions of cover window occurs after the backgrinding operation may be performed on silicon substrate 143, the width of cover window 150 may be less than the width of the backplane. For example, in further reference to FIG. 14E, cover window 150 has a width, w1, and backplane 140 has a width, w2, where w1 is less than w2. Further, at operation 1370, FIG. 14F shows a cutting operation through substrate 200 to complete singulation and form a plurality of optoelectronic structures 100, as illustrated in FIG. 14G.

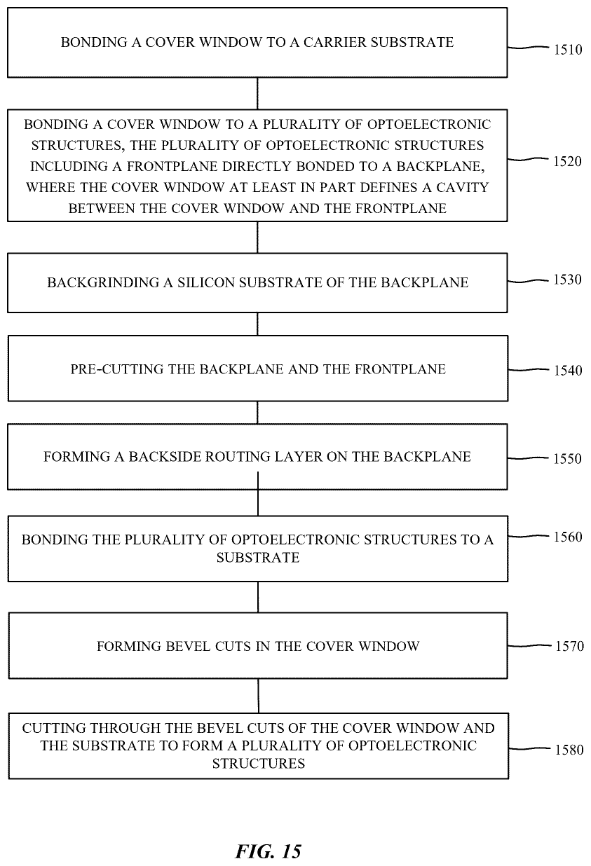

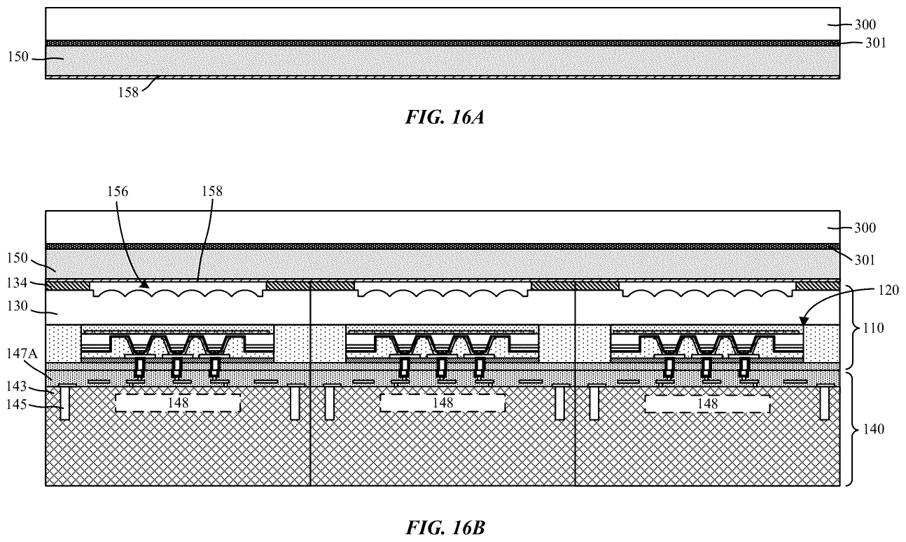

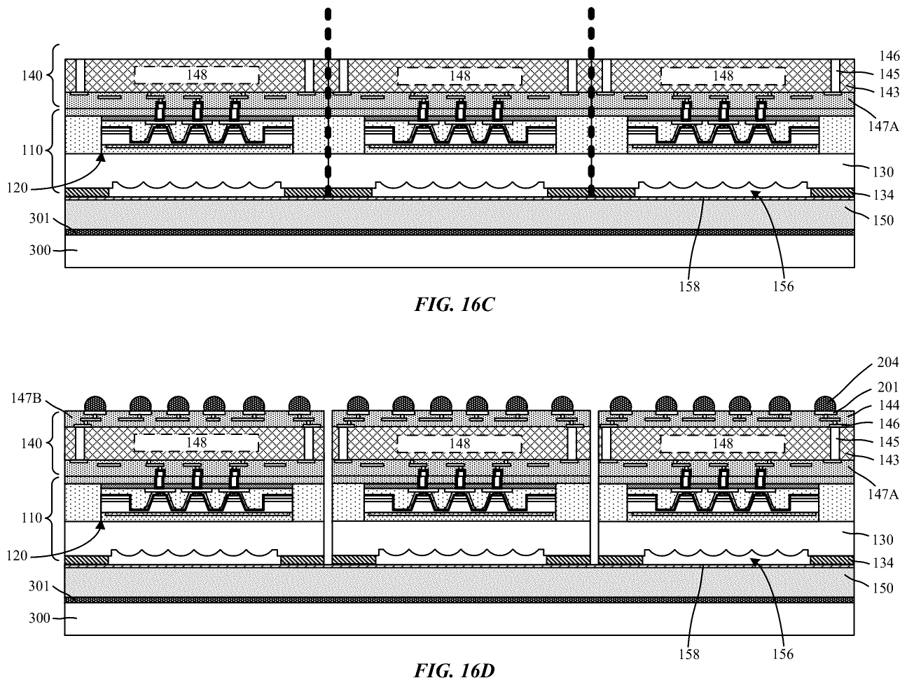

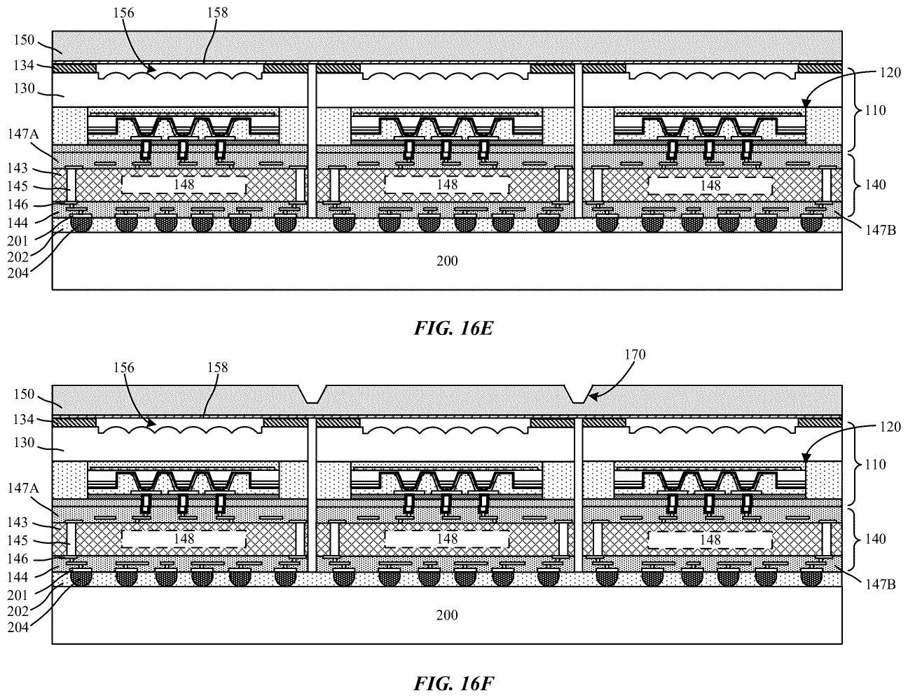

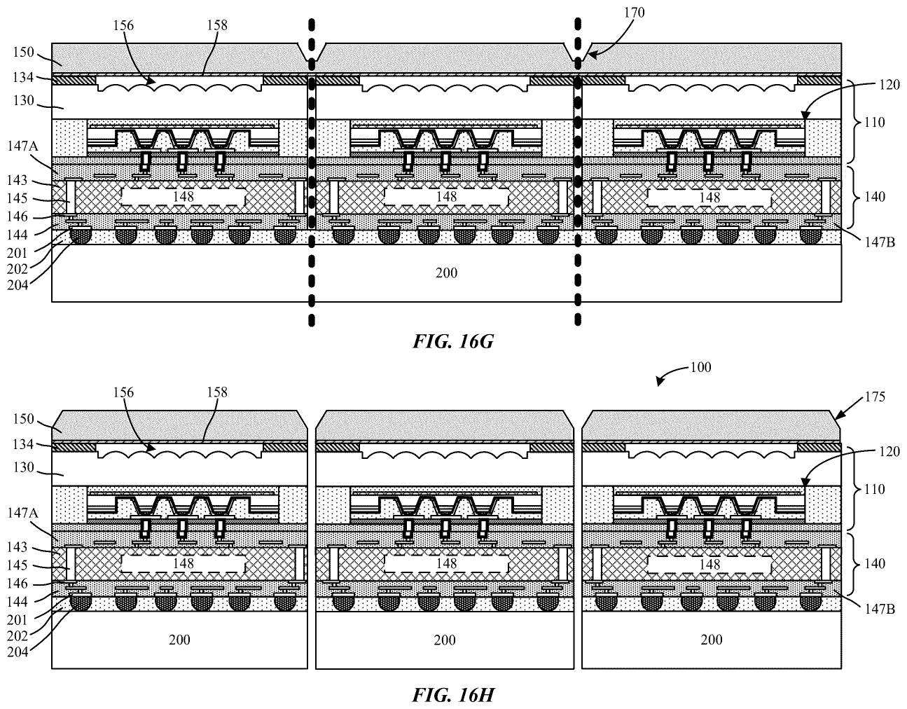

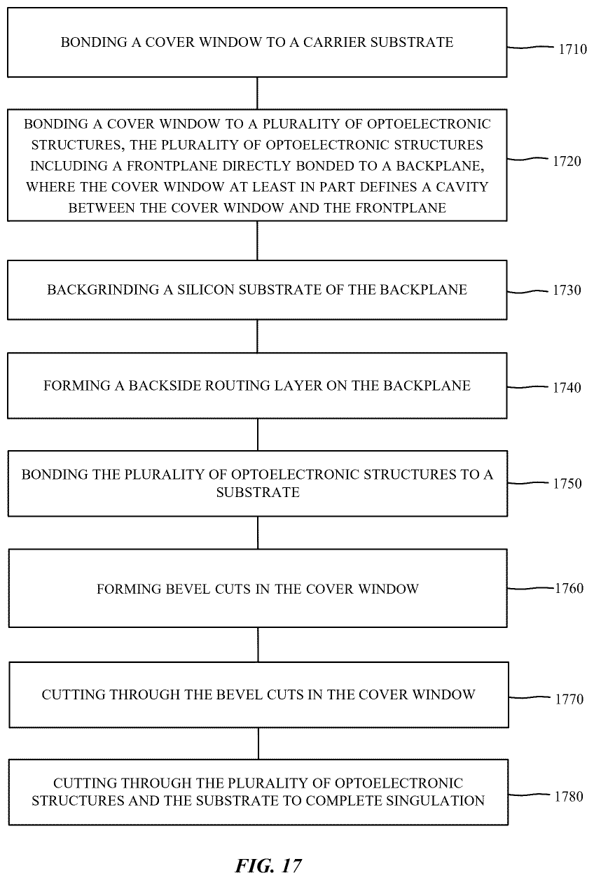

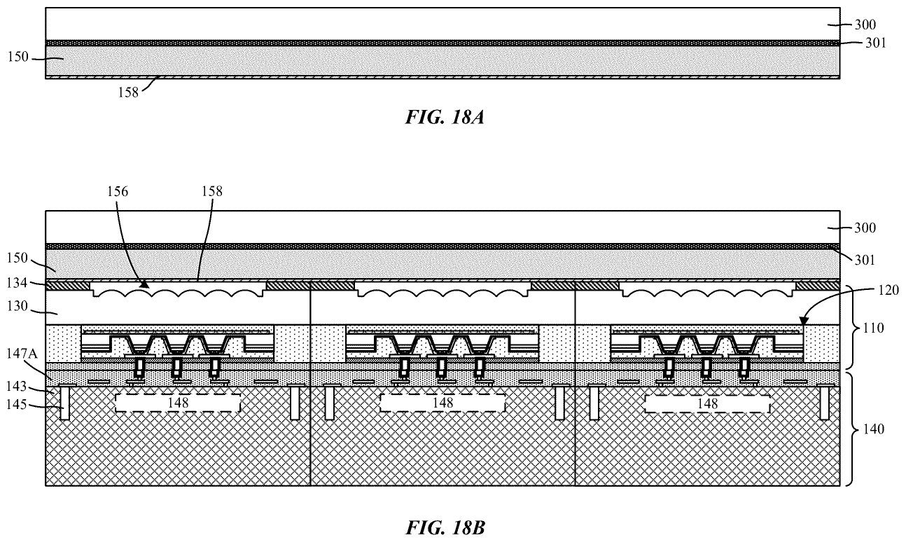

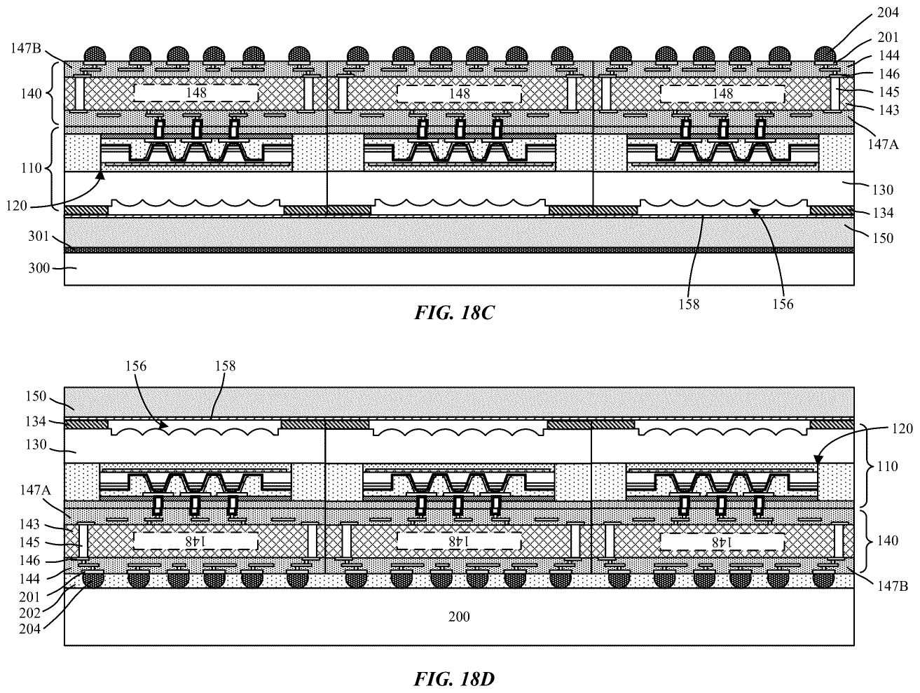

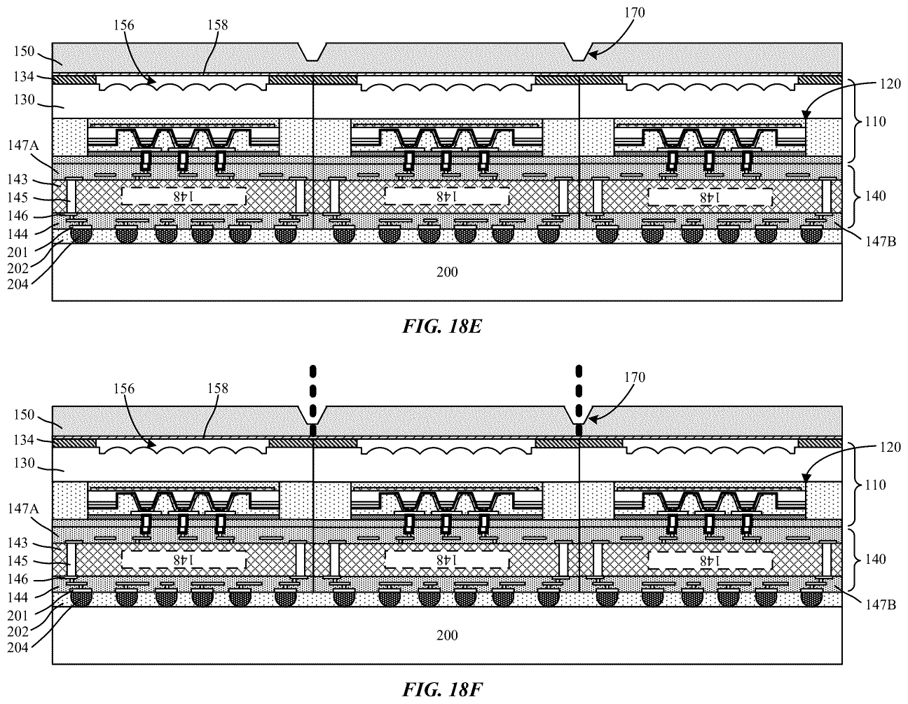

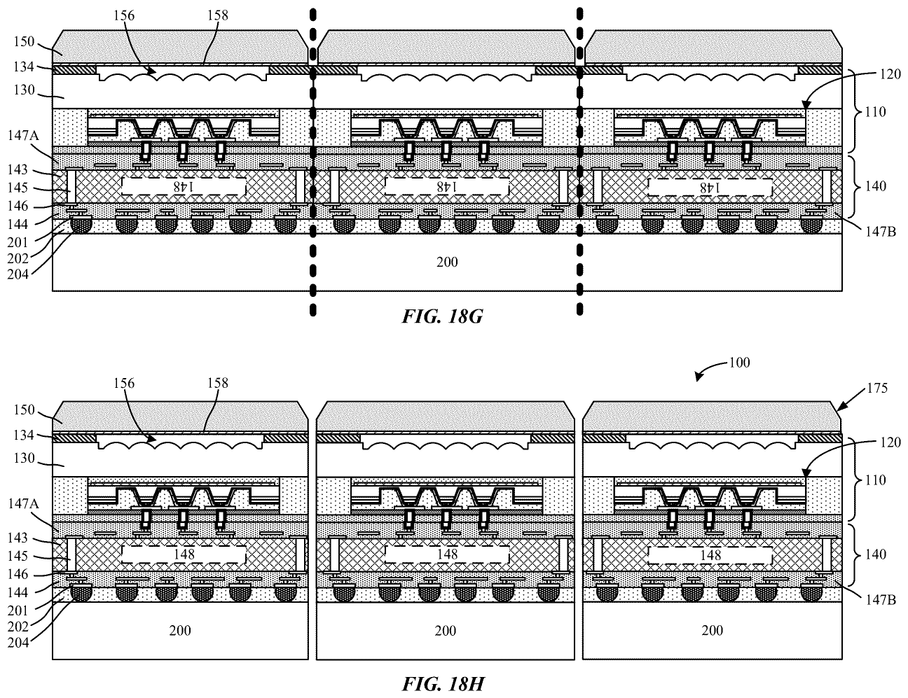

Referring now to FIG. 15 and FIGS. 16A-H, FIG. 15 is a flow chart and FIGS. 16A-16H are schematic cross-sectional side view illustrations of a method for assembling an optoelectronic structure that includes a cover window with chamfered edges in accordance with an embodiment. In the interest of clarity and conciseness, the method of FIG. 15 is described concurrently with the illustrations of FIGS. 16A-16H. It should be noted that the embodiments described in FIG. 15 and FIGS. 16A-H (as well as the embodiments described in FIG. 17 and FIGS. 18A-18H below) are substantially similar to the embodiments described in FIG. 13 and FIGS. 14A-14F except that the embodiments described here refer to cover widows that include chamfered edges. At operation 1510, FIG. 16A shows cover window 150 bonded to carrier substrate 300 by temporary adhesive 301. At operation 1520, FIG. 16B shows cover window 150 bonded to a plurality of optoelectronic structures that include frontplane 110 and backplane 140, where frontplane 110 may include optical layer 130 and coupons 120 directly bonded (e.g., hybrid bonded) to backplane 140. In embodiments, cover window 150 may be directly bonded to frontplane 110 (e.g., wafer-to-wafer fusion bonded) or by a bonding layer (e.g., optically clear adhesive, etc.), such as bonding layer 134. Further, the optoelectronic structure may include a cavity between cover window 150 and optical layer 130, such as cavity 156, where the cavity may be defined at least in part by any combination of its surrounding structures, similar to the examples described in FIGS. 2A-2C (e.g., frame structure, recessed cover window, recessed optical layer, etc.). In an embodiment, cavity 156 may include a low refractive index spacer material, where the refractive index of the spacer material may be in the range of 1.05-1.3.

Referring now to FIG. 16C, at operation 1530 a backgrinding operation may be performed on silicon substrate 143 to reveal through-silicon vias 145 followed by a pre-cut of backplane 140 and frontplane 110 at operation 1540. At operation 1550, FIG. 16D shows backside routing layer 147B formed by a damascene process to embed metal redistribution lines 146 within dielectric layer 144, as well as forming UBM 201 and placing solder bumps 204 on UBM 201. At operation 1560, FIG. 16E shows carrier substrate 300 flipped so that the plurality of optoelectronic structures may be bonded to substrate 200, where carrier substrate 300 may then be removed after bonding the plurality of optoelectronic structures to substrate 200. In some instances, after the bonding of the plurality of optoelectronic structures to substrate 200 (e.g., reflow, laser assisted bonding, etc.), underfill 202 may be applied to improve bonding strength. At operation 1570, FIG. 16F shows bevel cuts 170 in cover window 150, where the bevel cuts may be located over the pre-cuts in frontplane 110 and backplane 140 performed at operation 1540. At operation 1580, FIG. 16G shows a cutting operation through the bevel cuts of cover window 150 as well as substrate 200 to complete singulation and form a plurality of optoelectronic structures 100 that include cover windows with chamfered edges 175, as illustrated in FIG. 16H.

Referring now to FIG. 17 and FIGS. 18A-H, FIG. 17 is a flow chart and FIGS. 18A-18H are schematic cross-sectional side view illustrations of a method for assembling an optoelectronic structure that includes a cover window with chamfered edges in accordance with an embodiment. In the interest of clarity and conciseness, the method of FIG. 17 is described concurrently with the illustrations of FIGS. 18A-18H. At operation 1710, FIG. 18A shows cover window 150 bonded to carrier substrate 300 by temporary adhesive 301. At operation 1720, FIG. 18B shows cover window 150 bonded to a plurality of optoelectronic structures that include frontplane 110 and backplane 140, where frontplane 110 may include optical layer 130 and coupons 120 directly bonded (e.g., hybrid bonded) to backplane 140. In embodiments, cover window 150 may be directly bonded to frontplane 110 (e.g., wafer-to-wafer fusion bonded) or by a bonding layer (e.g., optically clear adhesive, etc.), such as bonding layer 134. Further, the optoelectronic structure may include a cavity between cover window 150 and optical layer 130, such as cavity 156, where the cavity may be defined at least in part by any combination of its surrounding structures, similar to the examples described in FIGS. 2A-2C (e.g., frame structure, recessed cover window, recessed optical layer, etc.). In an embodiment, cavity 156 may include a low refractive index spacer material, where the refractive index of the spacer material may be in the range of 1.05-1.3.

Referring now to FIG. 18C, at operation 1730 a backgrinding operation may be performed on silicon substrate 143 to reveal through-silicon vias 145 followed by the formation of backside routing layer 147B at operation 1740. In such instances, backside routing layer 147B may be formed by a damascene process to embed metal redistribution lines 146 within dielectric layer 144, as well as forming UBM 201 and placing solder bumps 204 on UBM 201. At operation 1750, FIG. 18D shows carrier substrate 300 flipped so that the plurality of optoelectronic structures may be bonded to substrate 200, where carrier substrate 300 may then be removed after bonding the plurality of optoelectronic structures to substrate 200. In some instances, after the bonding of the plurality of optoelectronic structures to substrate 200 (e.g., reflow, laser assisted bonding, etc.), underfill 202 may be applied to improve bonding strength. At operation 1760, FIG. 18E shows bevel cuts 170 in cover window 150 followed by a pre-cut of cover window 150 through the bevel cuts of the cover window at operation 1770 as illustrated in FIG. 18F. At operation 1780, FIG. 18G shows a cutting operation through frontplane 110, backplane 140 and substrate 200 to complete singulation and form a plurality of optoelectronic structures 100 that include cover windows with chamfered edges 175, as illustrated in FIG. 18H.

In utilizing the various aspects of the embodiments, it would become apparent to one skilled in the art that combinations or variations of the above embodiments are possible for forming an optoelectronic structure that includes a cover window attached at the wafer level. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An optoelectronic structure comprising:
a frontplane, the frontplane including an array of micro-sized diodes and a first bonding surface,
a backplane, the backplane including driving circuitry and a second bonding surface, wherein the second bonding surface is directly bonded to the first bonding surface;
a cover window located over the array of micro-sized diodes; and
a cavity located between the cover window and the array of micro-sized diodes, wherein a width of the cover window is less than a width of the backplane.

2. The optoelectronic structure of claim 1, wherein the cavity is an air gap.

3. The optoelectronic structure of claim 1, further including an optical layer over the array of micro-sized diodes.

4. The optoelectronic structure of claim 1, wherein the cover window comprises glass.

5. The optoelectronic structure of claim 1, wherein the cover window comprises sapphire.

6. The optoelectronic structure of claim 1, wherein the cover window includes an anti-reflective coating on an interior surface of the cover window.

7. The optoelectronic structure of claim 1, wherein the cover window is located over a display area of the array of micro-sized diodes.

8. The optoelectronic structure of claim 1, wherein the cover window is embedded within a frame structure, the frame structure including a sidewall that laterally surrounds the cavity.

9. The optoelectronic structure of claim 1, wherein the cover window includes a recess, the recess of the cover window including a sidewall that laterally surrounds the cavity.

10. The optoelectronic structure of claim 1, wherein the array of micro-sized diodes includes a recess, the recess of the array of micro-sized diodes including a sidewall that laterally surrounds the cavity.

11. The optoelectronic structure of claim 1, wherein a width of the cover window is equal to a width of the backplane.

12. The optoelectronic structure of claim 1, wherein the micro-sized diodes of the array of micro-sized diodes are light emitting diodes.

13. The optoelectronic structure of claim 1, wherein the micro-sized diodes of the array of micro-sized diodes are photodetectors.

14. The optoelectronic structure of claim 1, wherein the driving circuitry includes CMOS driving circuitry.

15. The optoelectronic structure of claim 1, wherein the driving circuitry includes an array of pixel driver chips.

16. The optoelectronic structure of claim 1, wherein the cover window spans over multiple arrays of micro-sized diodes.

17. The optoelectronic structure of claim 1, wherein the cover window includes a black matrix layer formed on one or more sidewalls of the cover window.

18. The optoelectronic structure of claim 1, wherein the cavity is filled with a low refractive index spacer material.

19. A method of assembling an optoelectronic structure comprising:
bonding a cover window to a frontplane, the frontplane including an array of micro-sized diodes and a first bonding surface, wherein the first bonding surface is directly bonded to a second bonding surface of a backplane, the backplane including driving circuitry;
singulating a plurality of optoelectronic structures, wherein the cover window at least in part defines a cavity between the cover window and the array of micro-sized diodes, and a width of the cover window is less than a width of the singulated backplane;
bonding the plurality of optoelectronic structures to a substrate; and
cutting through the substrate to complete singulation.

20. The method of claim 19, wherein bonding the cover window to the frontplane occurs after backgrinding of a silicon substrate of the backplane.

21. The method of claim 19, wherein the cavity is an air gap.

22. A method of assembling an electronic package comprising:
bonding a cover window to a frontplane, the frontplane including an array of micro-sized diodes and a first bonding surface, wherein the first bonding surface is directly bonded to a second bonding surface of a backplane, the backplane including driving circuitry;
backgrinding a silicon substrate of the backplane;
forming a backside routing layer on the backplane;
singulating a plurality of optoelectronic structures, wherein the cover window at least in part defines a cavity between the cover window and the array of micro-sized diodes, and a width of the cover window is equal to a width of the singulated backplane;
bonding the plurality of optoelectronic structures to a substrate; and
cutting through the substrate to complete singulation.

23. The method of claim 22, wherein the cavity is an air gap.

24. The method of claim 22, wherein the cavity is filled with a low refractive index spacer material.

25. A method of assembling an electronic package comprising:
bonding a cover window to a plurality of optoelectronic structures, the plurality of optoelectronic structures including a frontplane directly bonded to a backplane, wherein the cover window at least in part defines a cavity between the cover window and the frontplane;
backgrinding a silicon substrate of the backplane;
pre-cutting the backplane and the frontplane;
forming a backside routing layer on the backplane;
bonding the plurality of optoelectronic structures to a substrate;
forming bevel cuts in the cover window;
cutting through the cover window and the substrate to complete singulation.

26. A method of assembling an electronic package comprising:
bonding a cover window to a plurality of optoelectronic structures, the plurality of optoelectronic structures including a frontplane directly bonded to a backplane, wherein the cover window at least in part defines a cavity between the cover window and the frontplane;
backgrinding a silicon substrate of the backplane;
forming a backside routing layer on the backplane;
bonding the plurality of optoelectronic structures to a substrate;
forming bevel cuts in the cover window; and
cutting through the cover window, the plurality of optoelectronic structures and the substrate to complete singulation.
